(19) United States
(12) Patent Application Publication
(10) Pub. No.: US 2026/0052678 A1
(43) Pub. Date: Feb. 19, 2026

(54) SEMICONDUCTOR MEMORY DEVICE

(71) Applicant: Samsung Electronics Co., Ltd., Suwon-si (KR)

(72) Inventor: Sungjoon Park, Suwon-si (KR)

(21) Appl. No.: 19/290,115

(22) Filed: Aug. 4, 2025

(30) Foreign Application Priority Data
Aug. 19, 2024 (KR) 10-2024-0110585

(51) Int. Cl. H10B 12/00; H01L 23/00; H10D 1/68; H10D 80/30

(52) U.S. Cl. CPC H10B 12/482; H01L 24/08; H10B 12/315; H10B 12/485; H10B 12/488; H10B 12/50; H10D 1/716; H10D 80/30; H01L 2224/08145; H01L 2924/1436

(57) ABSTRACT

A semiconductor memory device includes a bit line extending in a first horizontal direction and including a contact, a first channel structure and a second channel structure, each arranged to be spaced apart from one another in the first horizontal direction on the bit line and the first channel structure including a first channel pattern, a first channel pad portion, and a first channel extension portion, the second channel structure including a second channel pattern, a second channel pad portion, and a second channel extension portion, and a first word line and a second word line each extending in a second horizontal direction orthogonal to the first horizontal direction and arranged adjacent to a respective channel pattern of the first channel structure and the channel pattern of the second channel structure.

### CROSS-REFERENCE TO RELATED APPLICATION

This application is based on and claims priority under 35 USC § 119 to Korean Patent Application No. 10-2024-0110585, filed on Aug. 19, 2024, in the Korean Intellectual Property Office, the disclosure of which is incorporated by reference herein in its entirety.

### BACKGROUND

The inventive concept relates to a semiconductor memory device, and more particularly, to a semiconductor memory device including vertical channel transistors.

As the design rules for semiconductor devices target reduced sizes of semiconductor devices, manufacturing technology has been developed to increase the integration density of semiconductor devices and improve operating speeds and yield. Accordingly, a transistor with a vertical channel has been proposed to expand the integration, resistance, and current driving capability of the transistor.

### SUMMARY

The inventive concept provides a semiconductor memory device with improved electrical characteristics.

According to an aspect of the inventive concept, there is provided a semiconductor memory device including a bit line extending lengthwise in a first horizontal direction and including a contact, a first channel structure and a second channel structure, each arranged to be spaced apart in the first horizontal direction on the bit line and the first channel structure including a first channel pattern, a first channel pad portion, and a first channel extension portion, the second channel structure including a second channel pattern, a second channel pad portion, and a second channel extension portion, wherein the first channel pad portion extends horizontally from an upper end of the first channel pattern, the first channel extension portion extends horizontally from a lower end of the first channel pattern, the second channel pad portion extends horizontally from an upper end of the second channel pattern, and the second channel extension portion extends horizontally from a lower end of the second channel pattern, and a first word line and a second word line each extending lengthwise in a second horizontal direction orthogonal to the first horizontal direction and arranged adjacent to a respective channel pattern of the first channel structure and the channel pattern of the second channel structure, and the contact of the bit line is connected to the first channel extension portion and the second channel extension portion.

According to another aspect of the inventive concept, there is provided a semiconductor memory device including a bit line extending lengthwise in a first horizontal direction and including a contact that protrudes upwards, a plurality of mold structures arranged on the bit line, the plurality of mold structures extending in a second horizontal direction orthogonal to the first horizontal direction, and arranged spaced apart from each other in the first horizontal direction, first channel structures and second channel structures arranged to alternate between a first channel structure and a second channel structure in the first horizontal direction on the bit line, a first word line extending in the second horizontal direction and arranged adjacent to the first channel structure and a second word line extending lengthwise in the second horizontal direction and arranged adjacent to the second channel structure, a gate dielectric film provided between the first channel structure and the first word line and between the second channel structure and the second word line, a first contact plug disposed on the first channel structure and a second contact plug disposed on the second channel structure, the first contact plug connected to the first channel structure and the second contact plug connected to the second channel structure, and a capacitor including a lower electrode disposed on the first contact plug and connected to the first contact plug, a capacitor dielectric film covering the lower electrode, and an upper electrode disposed on the capacitor dielectric film, wherein each of the first channel structures includes a first channel pattern extending in a vertical direction along a first sidewall of a corresponding mold structure of the plurality of mold structures, a first channel pad portion extending away from of the corresponding mold structure in the first horizontal direction from an upper end of the first channel pattern, and a first channel extension portion extending along a lower surface of the corresponding mold structure from a lower end of the first channel pattern, and each of the second channel structures includes a second channel pattern extending in a vertical direction along a second sidewall of the corresponding mold structure opposite the first sidewall, a second channel pad portion extending away from the corresponding mold structure in a direction opposite to the extension direction of the first channel pad portion from an upper end of the second channel pattern, and a second channel extension portion extending along a lower surface of the corresponding mold structure from a lower end of the second channel pattern opposite the upper end, the first contact plug is connected to the first channel pad portion, the second contact plug is connected to the second channel pad portion, and the contact of the bit line is connected to the first channel extension portion and the second channel extension portion.

According to another aspect of the inventive concept, there is provided a semiconductor memory device including a peripheral circuit structure including a peripheral circuit substrate and circuit gate structures, wherein the peripheral circuit substrate has a plurality of active regions defined by a circuit device separator, and each of the circuit gate structure is disposed in a corresponding active region of the plurality of active regions of the peripheral circuit substrate and forms a peripheral circuit transistor and a cell array structure overlapping the peripheral circuit structure in a vertical direction, wherein the cell array structure includes: a bit line extending lengthwise in a first horizontal direction and including a contact that protrudes upwards from the bit line, a plurality of mold structures arranged on the bit line, the plurality of mold structures extending in a second horizontal direction orthogonal to the first horizontal direction, and arranged to be spaced apart from each other in the first horizontal direction, a first channel structure and a second channel structure arranged in the first horizontal direction on the bit line, a first word line and a second word line each extending lengthwise in the second horizontal direction and arranged with the first word line adjacent to the first channel structure and the second word line adjacent to the second channel structure, a gate dielectric film provided between the first channel structure and the first word line and between the second channel structure and the second word line and having a hole filled with the contact of the bit line, an insulating pattern covering the first word line and the second word line and filling spaces between pairs of mold structures that are adjacent in the first horizontal direction among the plurality of mold structures, a first contact plug disposed on the first channel structure and connected to the first channel structure and a second contact plug disposed on the second channel structure and connected to the second channel structure, and a capacitor disposed on the first contact plug and including a lower electrode connected to the first contact plug, an upper electrode, and a capacitor dielectric film located between the lower electrode and the upper electrode, wherein the first channel structure includes a first channel pattern extending in the vertical direction along a first sidewall a mold structure of the plurality of mold structures in the first horizontal direction, a first channel pad portion extending away from the mold structure in the first horizontal direction from an upper end of the first channel pattern and connected to the first contact plug, and a first channel extension portion extending along a lower surface of the mold structure from the lower end of the first channel pattern, and the second channel structure includes a second channel pattern extending in the vertical direction along a second sidewall of the mold structure opposite the first sidewall, a second channel pad portion extending away from the mold structure in the first horizontal direction from an upper end of the second channel pattern in an extension direction opposite that of the first channel pad portion and connected to the second contact plug, and a second channel extension portion extending along a lower surface of the mold structure from the lower end of the second channel pattern, the first channel extension portion and the second channel extension portion connected to the contact of the bit line.

### BRIEF DESCRIPTION OF THE DRAWINGS

Embodiments will be more clearly understood from the following detailed description taken in conjunction with the accompanying drawings in which:

FIG. 1 is a block diagram of a semiconductor memory device according to embodiments;

FIGS. 2 and 3 are perspective views schematically illustrating semiconductor memory devices according to embodiments;

FIG. 4 is a planar layout schematically illustrating a semiconductor memory device according to embodiments, and FIG. 5 is a cross-sectional view of a semiconductor memory device according to embodiments;

FIGS. 6-7, 8A, 8B, 9A, 9B, 10A, 10B, 11A, 11B, 12A, 12B, 13A, 13B, 14A, 14B, 15A, 15B, and 16 to 17 are cross-sectional views and plan views illustrating a method of manufacturing a semiconductor memory device according to embodiments;

FIGS. 18A, 18B, 19A and 19B are cross-sectional views illustrating a method of manufacturing a semiconductor memory device according to embodiments, and FIG. 20 is a cross-sectional view of a semiconductor memory device according to embodiments;

FIGS. 21A, 21B, 22A, and 22B are cross-sectional views illustrating a method of manufacturing a semiconductor memory device according to embodiments, and FIG. 23 is a cross-sectional view of a semiconductor memory device according to embodiments;

FIGS. 24 and 25 are cross-sectional views illustrating a method of manufacturing a semiconductor memory device according to embodiments, and FIG. 26 is a cross-sectional view of a semiconductor memory device according to embodiments; and

FIGS. 27 and 28 are cross-sectional views of semiconductor memory devices according to embodiments, respectively.

### DETAILED DESCRIPTION OF THE EMBODIMENTS

The present disclosure now will be described more fully hereinafter with reference to the accompanying drawings, in which various embodiments are shown. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. The language of the claims should be referenced in determining the requirements of the invention.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Hereinafter, embodiments in the example embodiment will be described as follows with reference to the accompanying drawings. Items described in the singular herein may be provided in plural, as can be seen, for example, in the drawings. Thus, the description of a single item that is provided in plural should be understood to be applicable to the remaining plurality of items unless context indicates otherwise.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

Terms such as “same,” “equal,” “planar,” “coplanar,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

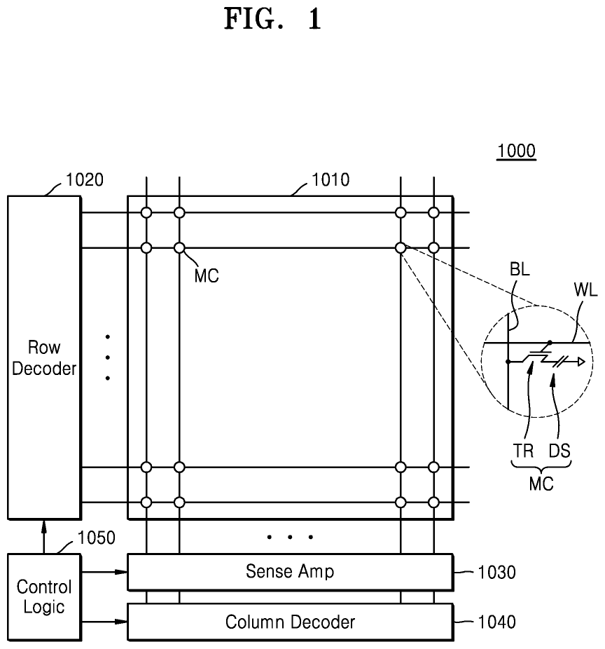

FIG. 1 is a block diagram of a semiconductor memory device 1000 according to embodiments.

Referring to FIG. 1, the semiconductor memory device 1000 may include a memory cell array 1010, a row decoder 1020, a sense amplifier 1030, a column decoder 1040, and a control logic 1050.

The memory cell array 1010 may include a plurality of memory cells MC arranged two-dimensionally or three-dimensionally. Each of the memory cells MC may be connected between a word line WL and a bit line BL that intersect each other.

Each memory cell MC may include a selection device TR and a data storage device DS, and the selection device TR and the data storage device DS may be electrically connected in series. The selection device TR may be connected between the data storage device DS and the word line WL, and the data storage device DS may be connected to the bit line BL through the selection device TR. The selection device TR may be a field effect transistor (FET), and in some embodiments, the data storage device DS may be, but is not limited to, a capacitor 140 as shown in FIG. 5. In some other embodiments, the data storage device DS may be a variable resistance pattern that may be switched between two resistance states by an electrical pulse applied to a memory clement. For example, the data storage device DS may include phase-change materials, perovskite compounds, transition metal oxides, magnetic materials, ferromagnetic materials, or antiferromagnetic materials having a crystal state changing depending on the amount of electric current.

The data storage device DS may be implemented with a magnetic tunnel junction pattern or a variable resistor. For example, the selection device TR may include a transistor, a gate electrode of the transistor may be connected to the word line WL, and drain/source terminals of the transistor may be connected to the bit line BL and the data storage device DS, respectively.

The row decoder 1020 may decode an address input from the outside and select one of the word lines WL of the memory cell array 1010. The address decoded by the row decoder 1020 may be provided to a sub-word line driver, and the sub-word line driver may provide a predetermined voltage to each of a selected word line WL and an unselected word line WL in response to control signals provided by control circuits.

The sense amplifier 1030 may detect and amplify a voltage difference between a bit line BL selected according to the address decoded from the column decoder 1040 and a reference bit line and output the same.

The column decoder 1040 may provide a data transmission path between the sense amplifier 1030 and an external device (e.g., a memory controller). The column decoder 1040 may decode an address input from the outside and select one of the bit lines BL.

The control logic 1050 may generate control signals that control operations of writing or reading data to or from the memory cell array 1010.

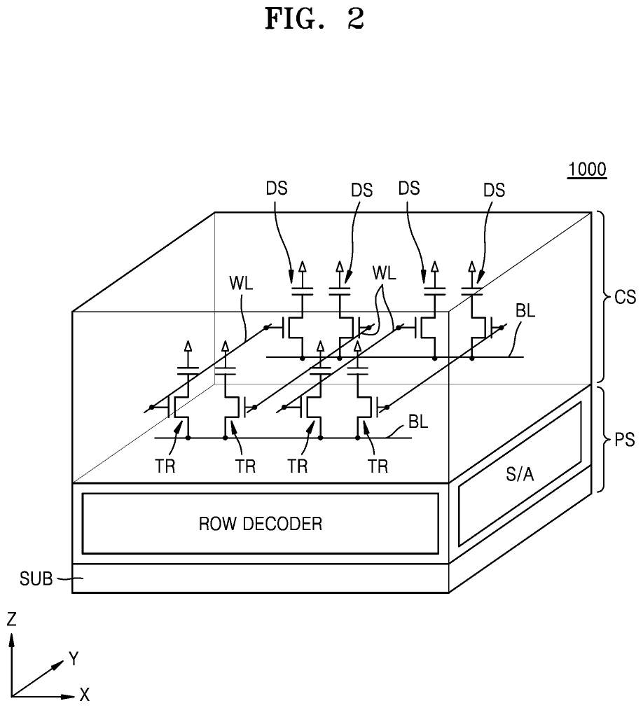

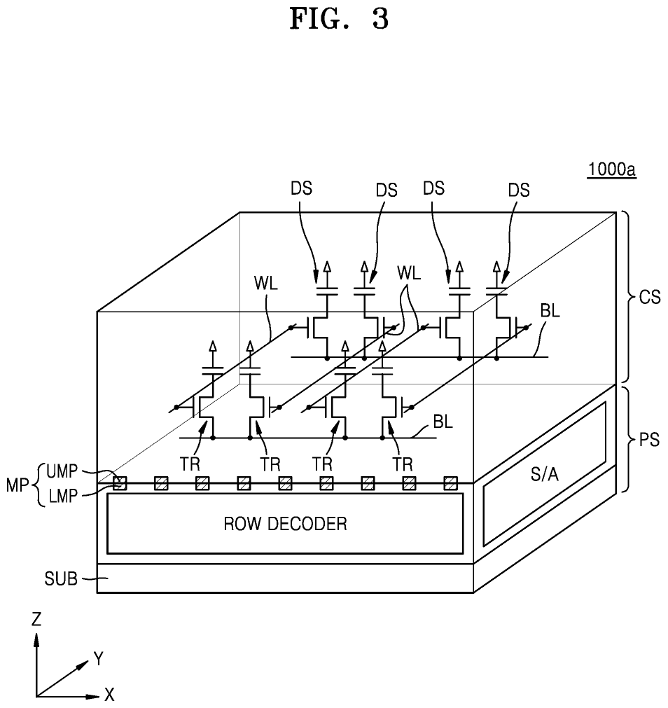

FIGS. 2 and 3 are perspective views schematically illustrating semiconductor memory devices according to embodiments.

Referring to FIG. 2, the semiconductor memory device 1000 may include a peripheral circuit structure PS on a semiconductor substrate SUB and a cell array structure CS on the peripheral circuit structure PS. The peripheral circuit structure PS may be provided on the semiconductor substrate SUB, and the cell array structure CS may be provided on the peripheral circuit structure PS.

The peripheral circuit structure PS may include core and peripheral circuits formed on a semiconductor substrate SUB. The core and peripheral circuits may include the row decoder 1020, the sense amplifier 1030, the column decoder 1040, and the control logic 1050 as described above with reference to FIG. 1. FIGS. 2 and 3 illustrate the row decoder and the sense amplifier among the core and peripheral circuits. The peripheral circuit structure PS may be provided between a semiconductor substrate SUB and the cell array structure CS in a vertical direction (a Z direction) perpendicular to an upper surface of the semiconductor substrate SUB.

The cell array structure CS may include bit lines BL, word lines WL, and the memory cells (MC in FIG. 1) therebetween. The memory cells (MC in FIG. 1) may be arranged two-dimensionally or three-dimensionally on a plane extending in a first horizontal direction (an X direction) and a second horizontal direction (a Y direction) intersecting each other to form the memory cell array (1010 in FIG. 1). The bit lines BL may extend in the first horizontal direction (the X direction), and the word lines WL may extend in a second horizontal direction (the Y direction). Each of the memory cells (MC in FIG. 1) may include the selection device TR and the data storage device DS.

In some embodiments, each memory cell (MC of FIG. 1) may include a vertical channel transistor VCT as the selection device TR. The vertical channel transistor may refer to a structure in which a channel length extends in the vertical direction (the Z direction). In some embodiments, the data storage device DS of each memory cell (MC in FIG. 1) may be a capacitor.

Referring to FIG. 3, a semiconductor memory device 1000a may include a peripheral circuit structure PS on the semiconductor substrate SUB, and the cell array structure CS on the peripheral circuit structure PS. The semiconductor substrate SUB, the peripheral circuit structure PS, and the cell array structure CS shown in FIG. 3 may be substantially the same or the same as the semiconductor substrate SUB, the peripheral circuit structure PS, and the cell array structure CS shown in FIG. 2, and thus, a redundant description may be omitted.

The peripheral circuit structure PS may be provided on the semiconductor substrate SUB, and the cell array structure CS may be bonded on the peripheral circuit structure PS. Lower metal pads LMP may be disposed on the highest layer of the peripheral circuit structure PS. The lower metal pads LMP may be electrically connected to the core and peripheral circuits included in the peripheral circuit structure PS. Upper metal pads UMP may be arranged on the lowest layer of the cell array structure CS. The upper metal pads UMP may be electrically connected to the memory cell array (1010 in FIG. 1) included in the cell array structure CS. The upper metal pads UMP may be in contact with and bonded to the lower metal pads LMP of the peripheral circuit structure PS. In some embodiments, the peripheral circuit structure PS may be bonded to the cell array structure CS in a metal-oxide hybrid bonding manner, and accordingly, the memory cell array (1010 in FIG. 1) included in the cell array structure CS may be electrically connected to the core and peripheral circuits included in the peripheral circuit structure PS. For example, the lower metal pads LMP and upper metal pads UMP corresponding to each other may be expanded by heat to come into contact with each other to become a plurality of bonding pads MP that are diffusion bonded to form an integrated body through diffusion of the metal atoms contained therein, and an insulating layer covering the lower metal pads LMP included in the peripheral circuit structure PS and an insulating layer covering the upper metal pads UMP included in the cell array structure CS may be bonded, while forming a covalent bond.

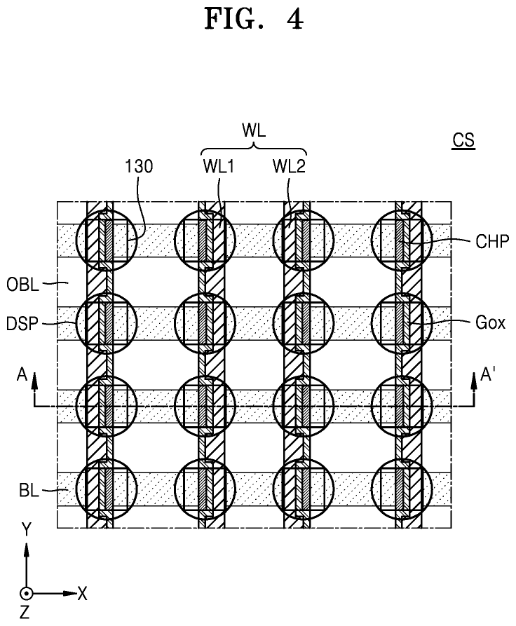

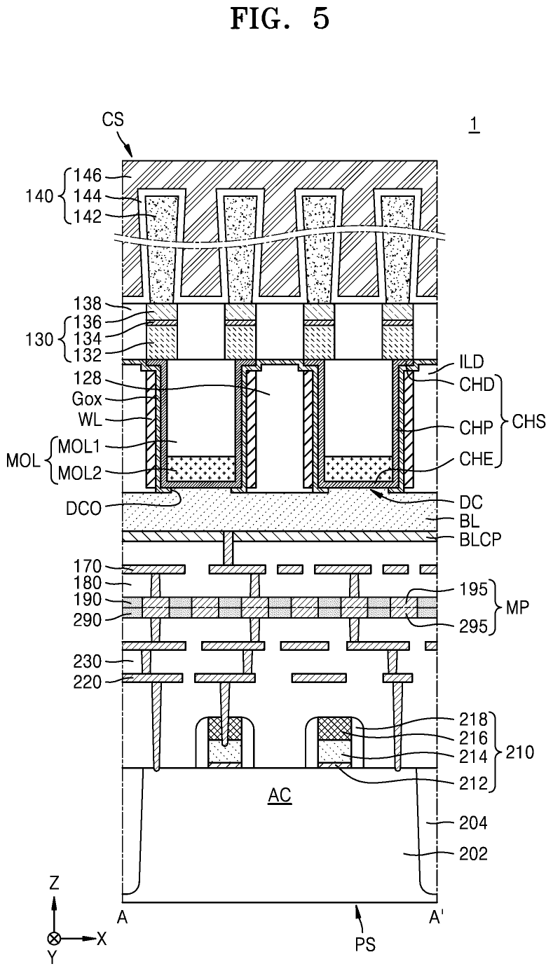

FIG. 4 is a planar layout schematically illustrating a portion of a semiconductor memory device 1 according to embodiments, and FIG. 5 is a cross-sectional view of the portion of the semiconductor memory device 1 of FIG. 4 according to embodiments.

Referring to FIGS. 4 and 5 together, the semiconductor memory device 1 may include the peripheral circuit structure PS and the cell array structure CS. In some embodiments, the semiconductor memory device 1 may have a cell on periphery (COP) structure in which the peripheral circuit structure PS and the cell array structure CS overlap each other in the vertical direction (the Z direction).

The peripheral circuit structure PS may include a peripheral circuit substrate 202 having a plurality of active regions AC defined by a circuit device separator 204, a plurality of circuit gate structures 210 arranged in the active regions AC of the peripheral circuit substrate 202, a peripheral circuit interconnection structure 220 electrically connected to the active regions AC and/or the circuit gate structures 210, and an inter-peripheral circuit interconnection insulating layer 230 covering the circuit gate structures 210 on the peripheral circuit substrate 202 and surrounding the peripheral circuit interconnection structure 220.

The peripheral circuit substrate 202 may include a semiconductor material, such as a group IV semiconductor material, a group III-V semiconductor material, or a group II-VI semiconductor material. The group IV semiconductor material may include, for example, silicon (Si), germanium (Ge), or silicon-germanium (Si—Ge). The group III-V semiconductor material may include, for example, gallium arsenide (GaAs), indium phosphide (InP), gallium phosphide (GaP), indium arsenide (InAs), indium antimony (InSb), or indium gallium arsenide (InGaAs). The group II-VI semiconductor material may include, for example, zinc telluride (ZnTe) or cadmium sulfide (CdS). The peripheral circuit substrate 202 may be a bulk wafer or an epitaxial layer. The peripheral circuit substrate 202 may be provided as a bulk wafer or an epitaxial layer. In another embodiment, the peripheral circuit substrate 202 may include a silicon-on-insulator (SOI) substrate or a germanium-on-insulator (GeOI) substrate. The peripheral circuit substrate 202 may be the semiconductor substrate SUB as shown in FIGS. 2 and 3. An active region AC may be defined by the circuit device separator 204 (e.g., a circuit device isolation film) on a peripheral circuit substrate 202, and the active region AC and the circuit gate structure 210 may constitute a peripheral circuit transistor.

The circuit gate structure 210 may include a circuit gate electrode 214 on the active region AC, a circuit gate insulating layer 212 located between the active region AC and the circuit gate electrode 214, a circuit gate capping layer 216 covering the circuit gate electrode 214, and a circuit gate spacer 218 covering side surfaces of the circuit gate insulating layer 212, the circuit gate electrode 214, and the circuit gate capping layer 216.

The peripheral circuit interconnection structure 220 may include a plurality of circuit interconnection lines and a plurality of circuit interconnection contacts. The peripheral circuit interconnection structure 220 may include a conductive material, such as copper (Cu), aluminum (Al), tungsten (W), silver (Ag), gold (Au), or combinations thereof. The inter-peripheral circuit interconnection insulating layer may include an insulating material that may include silicon oxide, silicon nitride, a low-k material, or combinations thereof. The low-k material may be a material having a lower dielectric constant than silicon oxide, and may include, for example, phosphosilicate glass (PSG), borophosphosilicate glass (BPSG), fluorosilicate glass (FSG), organosilicate glass (OSG), spin-on-glass (SOG), spin-on-polymer, or combinations thereof. In some embodiments, the inter-peripheral circuit interconnection insulating layer 230 may include an ultra low k (ULK) film having an ultra low dielectric constant K of about 2.2 to 2.4. The ULK film may include SiOC or SiCOH.

The cell array structure CS includes a plurality of bit lines BL, a plurality of channel structures CHS, a plurality of word lines WL, a plurality of gate dielectric films Gox located between the channel structures CHS and the word lines WL, a plurality of contact plugs 130 arranged on the channel structures CHS, and a plurality of capacitors 140 arranged on the contact plugs 130. The plurality of capacitors 140 may be a capacitor structure in which some capacitors of the plurality of capacitors 140 share elements such as a common capacitor dielectric film 144 and a common upper electrode 146.

The bit lines BL may be repeatedly arranged to extend lengthwise in the first horizontal direction (the X direction) and to be spaced apart from each other in the second horizontal direction (the Y direction) orthogonal to the first horizontal direction (the X direction). In some embodiments, the bit lines BL may be spaced apart from each other in the second horizontal direction (the Y direction) with a first interlayer insulating layer OBL therebetween. The first interlayer insulating layer OBL may fill the entire space between the bit lines BL.

For example, each of the bit lines BL may include doped polysilicon, a metal, a conductive metal nitride, a conductive metal silicide, a conductive metal oxide, or combinations thereof. Each of the bit lines BL may be formed of, but is not limited to, doped polysilicon, Al, Cu, Ti, Ta, Ru, W, Mo, Pt, Ni, Co, TiN, TaN, WN, NbN, TiAl, TiAlN, TiSi, WSi, TiSiN, TaSi, TaSiN, RuTiN, NiSi, CoSi, IrOx, RuOx, or combinations thereof. Each of the bit lines BL may include a single layer or multiple layers of the materials described above. In some embodiments, each of the bit lines BL may include two-dimensional (2D) and/or three-dimensional (3D) materials, for example, graphene, a carbon-based 2D material, carbon nanotubes, a 3D material, or combinations thereof. The first interlayer insulating layer OBL may include silicon oxide, silicon nitride, silicon dioxide, a low-k material, or combinations thereof. In some embodiments, the first interlayer insulating layer OBL may include silicon oxide, silicon nitride, or combinations thereof.

A plurality of insulating capping lines BLCP may cover the bit line BL. For example, in the vertical direction (the Z direction), the insulating capping lines BLCP may be arranged on one side of the bit lines BL, and the channel structures CHS may be arranged on the other side of the bit lines BL (e.g., an opposite side of the bit lines BL). For example, the insulating capping lines BLCP may be located below the bit lines BL to cover lower surfaces of the bit lines BL, and the channel structures CHS may be located above the bit lines BL. For example, each of the insulating capping lines BLCP may include silicon nitride, silicon oxynitride, silicon carbide, silicon carbonitride, or combinations thereof.

The bit lines BL may include contacts DC, respectively. The contacts DC may be portions of the bit lines BL protruding toward the channel structures CHS. For example, the contacts DC may be portions of the bit lines BL respectively protruding upwards. The contacts DC may be portions of the respective bit lines BL that fill holes DCO that penetrate through the gate dielectric films Gox.

A cell interconnection structure 170 and an inter-cell interconnection insulating layer 180 surrounding the cell interconnection structure 170 may be disposed below the insulating capping lines BLCP and the first interlayer insulating layer OBL. The cell interconnection structure 170 may include a plurality of cell interconnection lines and a plurality of cell interconnection contacts. The cell structure 170 may include a conductive material, such as copper (Cu), aluminum (Al), tungsten (W), silver (Ag), gold (Au), or combinations thereof. The inter-cell interconnection insulating layer 180 may include an insulating material, which may include silicon oxide, silicon nitride, a low-k material, or combinations thereof. In some embodiments, some of the cell interconnection contacts of the cell interconnection structure 170 may be connected to at least some of the bit lines BL through at least some of the insulating capping lines BLCP.

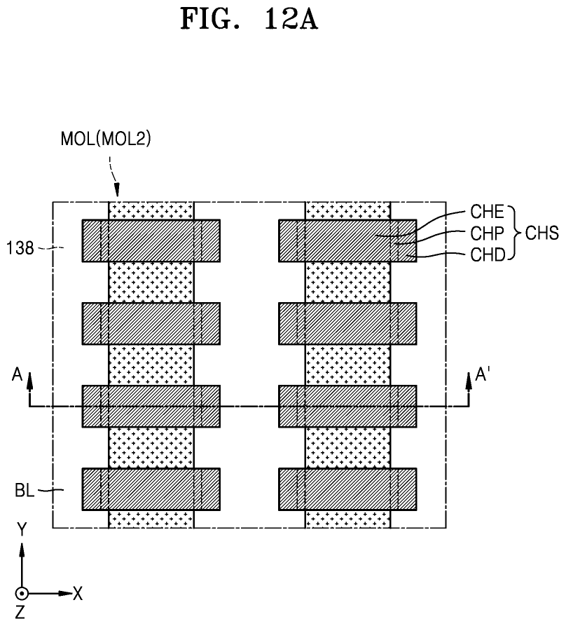

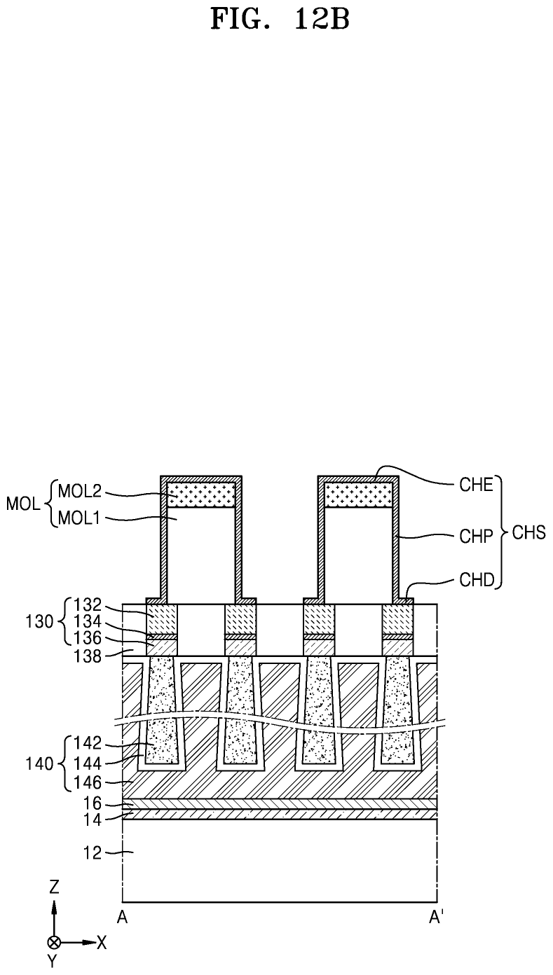

In some embodiments, each of the channel structures CHS may include a channel pad portion CHD, a channel extension portion CHE, and a channel pattern CHP located between the channel pad portion CHD and the channel extension portion CHE. The channel pad portion CHD, the channel pattern CHP, and the channel extension portion CHE included in each of the channel structures CHS may be formed integrally. In some embodiments, the channel pad portions CHD, the channel pattern CHP, and the channel extension portion CHE included in each of the channel structures CHS may have substantially the same horizontal width or the same horizontal width in the second horizontal direction (the Y direction), as shown in FIG. 12A.

The channel patterns CHP may be repeatedly arranged in the first horizontal direction (the X direction) and the second horizontal direction (the Y direction) on the bit lines BL. Each of the contact plugs 130 may be disposed on the channel pad portion CHD of a corresponding channel structure CHS among the channel structures CHS. In some embodiments, the channel extension portion CHE may cover a portion of the contact DC of the bit line BL connected thereto. In some embodiments, a channel extension portion CHE of a first channel structure CHS and a channel extension portion CHE of an adjacent second channel structure CHS may cover the contact DC of the bit line BL connected to the first channel structure CHS and the second channel structure CHS. In some embodiments, at least a portion of each of the channel pad portion CHD and the channel extension portion CHE may be formed with an impurity region that functions as a source/drain region.

The channel pattern CHP of each of the channel structures CHS may extend in the vertical direction (the Z direction) between a bitline BL from among the bit lines BL and a contact plug 130 from among the contact plugs 130. For example, the channel pattern CHP of each of the channel structures CHS may extend in the vertical direction (the Z direction) along a sidewall of a mold structure MOL (e.g., the sidewall may be a sidewall in the first horizontal direction (the X direction)). The channel pad portion CHD and the channel extension portion CHE of the channel structure CHS may extend from respective opposing vertical ends (e.g., a lower end and an upper end) of the channel pattern CHP. The channel pad portion CHD and the channel extension portion CHE of the channel structure CHS may extend in opposite directions along the first horizontal direction (the X direction) from respective opposing vertical ends of the channel pattern CHP. A pair of channel pad portions CHD included in a pair of channel structures CHS adjacent to each other in the first horizontal direction (the X direction) may extend in opposite directions from an upper vertical end of the channel pattern CHP in the first horizontal direction (the X direction). For example, a pair of channel pad portions CHD included in a pair of channel structures CHS including a pair of channel patterns CHP extending in the vertical direction (the Z direction) along opposite sidewalls of the mold structure MOL (e.g., opposite sidewalls in the first horizontal direction (the X direction)) may extend away from the mold structure MOL in opposite directions from the upper vertical end of the channel pattern CHIP in the first horizontal direction (the X direction). A pair of channel structures CHS including a pair of channel patterns CHP extending in the vertical direction (the Z direction) along opposite sidewalls of the mold structure MOL (e.g., opposite sidewalls in the first horizontal direction (the X direction)) may share a channel extension (e.g., the channel extension portion of a first channel structure CHS and the channel extension portion of a second channel structure CHS may together form a channel extension shared by the two channel structures CHS). For example, the channel extension shared by a pair of channel structures CHS including a pair of channel patterns CHP extending in the vertical direction (the Z direction) along opposite sidewalls of the mold structure MOL (e.g., opposite sidewalls in the first horizontal direction (the X direction)) may extend along the mold structure MOL, for example, along a lower surface of the mold structure MOL from a first channel pattern CHP to a second channel patter CHP, and cover the lower surface of the mold structure MOL.

In some embodiments, each of the channel structures CHS may include a semiconductor material. For example, each of the channel structures CHS may include single crystal silicon, polycrystalline silicon, or amorphous silicon. In some other embodiments, each of the channel structures CHS may include at least one of Ge, SiGe, SiC, GaAs, InAs, or InP. In some other embodiments, each of the channel structures CHS may include an oxide semiconductor material. For example, each of the channel structures CHS may include a binary or ternary oxide semiconductor material including a first metal element, a ternary oxide semiconductor material including different first and second metal elements, and a quaternary oxide semiconductor material including different first, second, and third metal elements.

The binary or ternary oxide semiconductor material may be, for example, one of ZnO (zinc oxide, ZnₓO), GaO (gallium oxide, GaₓO), TiO (titanuim oxide, TiₓO), SnO (tin oxide, SnₓO), ZnON (zinc oxynitride, ZnₓO_{y}N), IZO (indium zinc oxide, InₓZn_{y}O), GZO (gallium zinc oxide, GaₓZn_{y}O), TZO (tin zinc oxide, SnₓZn_{y}O), or TGO (tin gallium oxide, SnₓGa_{y}O), but is not limited thereto. The quaternary oxide semiconductor material may be, for example, one of IGZO (indium gallium zinc oxide, InₓGa_{Y}Zn_{z}O), IGSO (indium gallium silicon oxide, InₓGa_{y}Si_{z}O), ITZO (indium tin zinc oxide, InₓSn_{Y}Zn_{z}O), IGTO (indium gallium tin oxide, InₓGa_{Y}Sn_{z}O), ZZTO (zirconium zinc tin oxide, Zr_{X}Zn_{y}Sn_{z}O), HIZO (hafnium indium zinc oxide, HfₓIn_{Y}Zn_{z}O), GZTO (gallium zinc tin oxide, Ga_{X}Zn_{y}Sn_{z}O), AZTO (aluminium zinc tin oxide, Al_{X}Zn_{y}Sn_{z}O), YGZO (ytterbium gallium zinc oxide, YbₓGa_{Y}Zn_{z}O), or IAZO (indium aluminum zinc oxide), but is not limited thereto.

In some embodiments, each of the channel structures CHS may include a crystalline oxide semiconductor material or an amorphous oxide semiconductor material. When each of the channel structures CHS includes a crystalline oxide semiconductor material, each of the channel structures CHS may have at least one crystallinity among single crystalline, polycrystalline, spinel, or c-axis aligned crystalline (CAAC). In some embodiments, each of the channel structures CHS may be formed by stacking at least two layers including a first layer formed of a crystalline oxide semiconductor material and a second layer formed of an amorphous oxide semiconductor material. For example, each of the channel structures CHS may be formed by sequentially stacking a first layer formed of a crystalline oxide semiconductor material, a second layer formed of an amorphous oxide semiconductor material, and a third layer formed of a crystalline oxide semiconductor material. In some embodiments, each of the channel structures CHS may include a 2D semiconductor material, and the 2D semiconductor material may include, for example, graphene, carbon nanotubes, or combinations thereof. In some embodiments, each of the channel structures CHS may have a bandgap energy greater than a bandgap energy of silicon. For example, each of the channel structures CHS may have a band gap energy of about 1.5 eV to about 5.6 eV. In some embodiments, each of the channel structures CHS may have a bandgap energy of about 2.0 eV to about 4.0 eV.

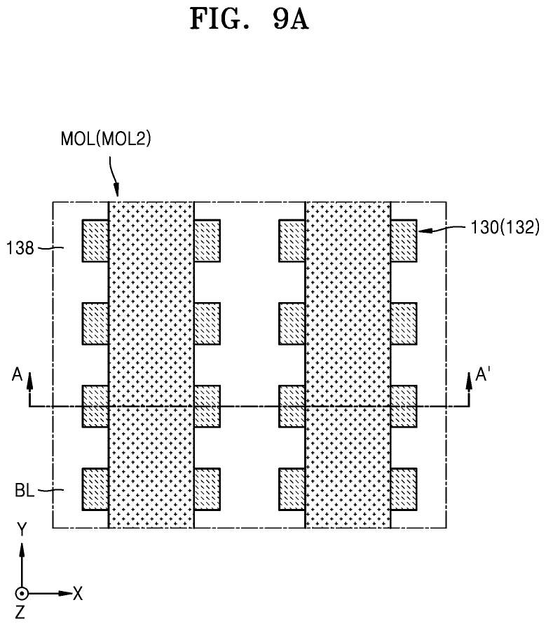

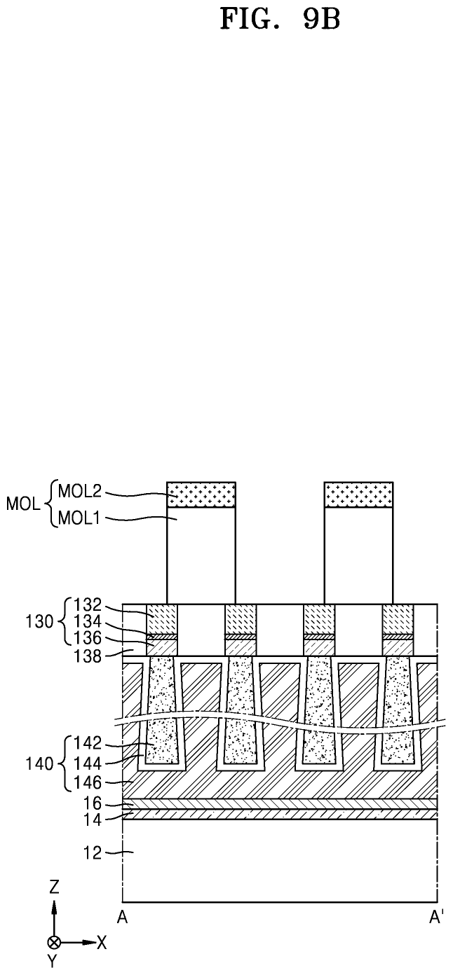

In some embodiments, a plurality of mold structures MOL may be repeatedly arranged to extend in the second horizontal direction (the Y direction) and spaced apart from each other in the first horizontal direction (the X direction), as shown in FIG. 9B. The channel patterns CHP included in the channel structures CHS may be arranged to be spaced apart from each other along both sides of the mold structures MOL in the first horizontal direction (the X direction), thereby respectively forming a plurality of rows in which the channel patterns CHP are apart from each other in the second horizontal direction (the Y direction). In some embodiments, each of the mold structures MOL may have a stack structure of a first mold layer MOL1 and a second mold layer MOL2. The first mold layer MOL1 may be disposed to be adjacent to the channel pad portion CHD, and the second mold layer MOL2 may be disposed to be adjacent to the channel extension portion CHE. For example, the second mold layer MOL2 and the first mold layer MOL1 may be sequentially stacked on the channel extension portion CHE. For example, the first mold layer MOL1 may include an oxide, and the second mold layer MOL2 may include a nitride.

The word lines WL may be repeatedly arranged to extend lengthwise in the second horizontal direction (the Y direction) and to be spaced apart from each other in the first horizontal direction (the X direction). For example, each of the word lines WL may extend in the second horizontal direction (the Y direction) between the bit lines BL and the contact plugs 130. Each of the word lines WL may be arranged to be spaced apart from each other in the second horizontal direction (the Y direction), may be arranged adjacent to the channel patterns CHP forming a plurality of rows, and may extend lengthwise in the second horizontal direction (the Y direction). The word lines WL may include a plurality of first word lines WL1 and a plurality of second word lines WL2 that are alternately arranged in the first horizontal direction (the X direction). The first word line WL may cover a first side surface of the mold structure MOL in the first horizontal direction (the X direction), may be adjacent to the channel patterns CHP that form a row in the second horizontal direction (the Y direction), and may extend lengthwise in the second horizontal direction (the Y direction), and the second word line WL may cover a second side surfaces of the mold structure MOL opposite to the first side surface in the first horizontal direction (the X direction), may be adjacent to the channel patterns CHP that form a row in the second horizontal direction (the Y direction), and may extend lengthwise in the second horizontal direction (the Y direction). The first word line WL1 and the second word line WL2 covering opposing side surfaces of the mold structure MOL in the first horizontal direction (the X direction) may be provided symmetrically based on the mold structure MOL. Each of the first word line WL1 and the second word line WL2 may have an inner wall facing the corresponding channel structures CHS and mold structures MOL and an outer wall opposite to the inner wall. The inner walls of the first word line WL1 and the second word line WL2 may be arranged to face each other. The channel structure CHS located between the first word line WL1 and the corresponding mold structure MOL may be referred to as a first channel structure, and the channel structure CHS located between the second word line WL2 and the corresponding mold structure MOL may be referred to as a second channel structure. The channel pad portion CHD and the channel pattern CHP of the first channel structure may be referred to as a first channel pad portion and a first channel pattern, respectively, and the channel pad portion CHD and the channel pattern CHP of the second channel structure may be referred to as a second channel pad portion and a second channel pattern, respectively. The first channel structure and the second channel structure, which are located at opposite sides of a mold structure MOL in the first horizontal direction (the X direction) may share the channel extension portion CHE covering an upper surface of one mold structure MOL. The channel pattern CHP of the first channel structure and the channel pattern CHP of the second channel structure may respectively have inner walls facing each other and outer walls opposite to the inner walls. The inner wall of the first word line WL1 and the outer wall of the channel pattern CHP of the first channel structure may face each other, and the inner wall of the second word line WL2 and the outer wall of the channel pattern CHP of the second channel structure may face each other.

The gate dielectric films Gox may be located between the word lines WL and the channel structures CHS. The gate dielectric films Gox may extend in the second horizontal direction (the Y direction) between the word lines WL and the mold structures MOL and the channel structures CHS corresponding thereto. The gate dielectric films Gox may have a plurality of holes DCO on a lower surface of the mold structures MOL. The holes DCO may be formed so that the gate dielectric films Gox do not cover portions of the lower surfaces of mold structures MOL and may be filled by the contacts DC, which are portions of the bit lines BL.

In some embodiments, each of the word lines WL may be formed of a metal, a conductive metal nitride, a conductive metal silicide, a conductive metal oxide, doped polysilicon, or combinations thereof. For example, each of the word lines WL may include, but is not limited to, Ti, TiN, Ta, TaN, Mo, Ru, W, WN, TiSiN, WSiN, doped polysilicon, or combinations thereof.

According to embodiments, the gate dielectric film Gox may be formed of a silicon oxide film, a high-k film, or combinations thereof. The term “high-k film” as used herein refers to a dielectric film having a higher dielectric constant than silicon oxide. In embodiments, the gate dielectric film Gox may include silicon oxide, hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), or lead scandium tantalum oxides (PbScTaO). The word lines WL, the channel structures CHS, and a plurality of gate dielectric films Gox arranged between the bit lines BL and the contact plugs 130 may form a plurality of vertical channel transistors. In this specification, the vertical channel transistors may be referred to as a vertical channel transistor structure.

Between a pair of mold structures MOL adjacent in the first horizontal direction (the X direction), a pair of word lines WL and an insulating pattern 128 covering the pair of word lines WL and filling a space between a pair of mold structures MOL may be arranged. The insulating pattern 128 may include silicon oxide, silicon nitride, or combinations thereof.

First ends of the word lines WL facing the contact plugs 130 in the vertical direction (the Z direction), for example, each of the uppermost ends of the word lines WL, may be located at a lower vertical level than each of the uppermost ends of the channel structures CHS and the channel patterns CHP of the channel structures CHS. Second ends of the word lines WL facing the bit lines BL in the vertical direction (the Z direction), which are opposite to the first ends, for example, each of the lowermost ends of the word lines WL, may be located at a vertical level lower than the lowermost ends of the mold structures MOL (i.e., the lower surfaces of the mold structures MOL) and higher than the lowermost ends of the gate dielectric films Gox. In some embodiments, each of the lowermost ends of the word lines WL may be located at substantially the same vertical level or the same vertical level as that of the lowermost end of each of the channel structures CHS and the channel extension portions CHE of the channel structures CHS, but is not limited thereto. For example, each of the lowermost ends of the word lines WL may be located at a vertical level that is slightly higher or slightly lower than the lowermost end of each of the channel structures CHS and the channel extension portions CHE of the channel structures CHS.

The insulating patterns 128 may cover the second ends of the word lines WL facing the bit lines BL in the vertical direction (the Z direction), for example, the lowermost ends of the word lines WL. In some embodiments, the surfaces of the insulating patterns 128 facing the bit lines BL, for example, lower surfaces of the insulating patterns 128, may be located at the same vertical level as that of the lowermost ends of the gate dielectric films Gox.

The contact plugs 130 may be spaced apart from the bit lines BL with the channel structures CHS therebetween in the vertical direction (the Z direction). The contact plugs 130 may be arranged in a matrix arrangement to be apart from each other in the first horizontal direction (the X direction) and the second horizontal direction (the Y direction). The contact plugs 130 may have various shapes, such as circular, oval, rectangular, square, diamond, or hexagonal, from a planar perspective. The contact plugs 130 may be connected to the channel structures CHS, respectively. For example, each of the contact plugs 130 may be connected to a channel pad portion CHD of the corresponding channel structures CHS.

In some embodiments, the contact plugs 130 may each include a metal, a conductive metal nitride, a metal silicide, doped polysilicon, or combinations thereof. For example, the contact plugs 130 may each include Ti, TiN, Ta, TaN, Mo, Ru, W, WN, Co, Ni, TiSi, TiSiN, WSi, WSiN, TaSi, TaSiN, RuTiN, CoSi, NiSi, doped polysilicon, or combinations thereof.

In some embodiments, each of the contact plugs 130 may include a first conductive pattern 132, a second conductive pattern 134, and a third conductive pattern 136 sequentially stacked on the channel structures CHS. For example, the first conductive pattern 132 may include doped polysilicon, the second conductive pattern 134 may include metal silicide, and the third conductive pattern 136 may include metal, but are not limited thereto.

A second interlayer insulating layer 138 may surround the contact plugs 130. Each of the contact plugs 130 may contact a corresponding channel structure CHS through the second interlayer insulating layer 138. The contact plugs 130 may be spaced apart from each other in the horizontal direction (the X direction and/or Y direction) with the second interlayer insulating layer 138 therebetween. In some embodiments, the second interlayer insulating layer 138 may include silicon oxide, silicon nitride, or combinations thereof.

A plurality of capacitors 140 may be arranged on the contact plugs 130 and the second interlayer insulating layer 138. The capacitors 140 may include a plurality of lower electrodes 142 connected to the contact plugs 130, a capacitor dielectric film 144 conformally covering a surface of each of the lower electrodes 142, and an upper electrode 146 covering the lower electrodes 142 with the capacitor dielectric film 144 therebetween. Each of the lower electrodes 142 may be connected to a corresponding channel pattern CHP through one contact plug 130 from among the contact plugs 130. The third conductive pattern 136 included in each of the contact plugs 130 may function as a landing pad in contact with a corresponding lower electrode 142 from among the lower electrodes 142.

Each of the lower electrodes 142 may have a pillar shape, i.e., a column shape with the interior filled to have a circular horizontal cross-section, but is not limited thereto. In some embodiments, each of the lower electrodes 142 may have a cylindrical shape with a closed bottom. In some embodiments, the lower electrodes 142 may be arranged in a matrix form in a row in each of the first horizontal direction (the X direction) and the second horizontal direction (the Y direction). In some other embodiments, the lower electrodes 1420 may be arranged in a honeycomb shape in a zigzag manner with respect to the first horizontal direction (the X direction) or the second horizontal direction (the Y direction). The lower electrodes 142 may include, for example, a metal, such as silicon, tungsten or copper doped with impurities, or a conductive metal compound, such as titanium nitride.

The capacitor dielectric film 144 may conformally cover the surfaces of the lower electrodes 142. In some embodiments, the capacitor dielectric film 144 may be formed of a high-k film. In some embodiments, the capacitor dielectric film 144 may be formed of a metal oxide including hafnium (Hf), zirconium (Zr), aluminum (Al), niobium (Nb), cerium (Ce), lanthanum (La), tantalum (Ta), or titanium (Ti). In some embodiments, each of the lower electrodes 142 and upper electrodes 146 may be formed of a metal, a conductive metal oxide, a conductive metal nitride, a conductive metal oxynitride, or combinations thereof. In some embodiments, each of the lower electrodes 142 and upper electrodes 146 may include Nb, Nb oxide, Nb nitride, Nb oxynitride, Ti, Ti oxide, Ti nitride, Ti oxynitride, Co, Co oxide, Co nitride, Co oxynitride, Sn, Sn oxide, Sn nitride, Sn oxynitride, or combinations thereof. In some other embodiments, each of the lower electrodes 142 and upper electrodes 146 may include TaN, TiAlN, TaAlN, V, VN, Mo, MoN, W, WN, Ru, RuO₂, SrRuO₃, Ir, IrO₂, Pt, PtO, SRO(SrRuO₃), BSRO((Ba, Sr)RuO₃), CRO(CaRuO₃), LSCO((La,Sr)CoO₃), or combinations thereof. However, the constituent materials of each of the lower electrodes 142 and upper electrodes 146 are not limited to those listed above. In some embodiments, the upper electrode 146 may have a stacked structure including, in addition to the metal material, at least one of a doped semiconductor material layer and an interfacial layer. The doped semiconductor material layer may include, for example, at least one of doped polysilicon and doped polycrystalline silicon germanium (polySiGe). The main electrode layer may include a metal material. The interfacial layer may include, for example, at least one of a metal oxide, a metal nitride, a metal carbide, or a metal silicide.

A plurality of upper metal pads 195 electrically connected to the cell interconnection structure 170 and a first bonding insulating layer 190 surrounding the upper metal pads 195 may be arranged below the cell interconnection structure 170 and the inter-cell interconnection insulating layer 180. A plurality of lower metal pads 295 electrically connected to the peripheral circuit interconnection structure 220 and a second bonding insulating layer 290 surrounding the lower metal pads 295 may be arranged on the peripheral circuit interconnection structure 220 and the inter-peripheral circuit interconnection insulating layer 230. Each of the first bonding insulating layer 190 and the second bonding insulating layer 290 may include silicon oxide or silicon carbon nitride (SiCN). In some embodiments, the peripheral circuit structure PS may be bonded to the cell array structure CS in a metal-oxide hybrid bonding manner. The first bonding insulating layer 190 and the second bonding insulating layer 290 may be in contact with and bonded to each other, while forming a covalent bond. The upper metal pads 195 and the lower metal pads 295 corresponding to each other may be expanded by heat, come into contact with each other, and then become the bonding pads MP that are integrated through diffusion bonding of the metal atoms contained therein. The upper metal pad 195 and the lower metal pad 295 may be the upper metal pad UMP and the lower metal pad LMP, respectively, shown in FIG. 3.

In the semiconductor memory device 1 according to the inventive concept, because the bit line BL is in contact with and connected to the channel extension portion CHE of the channel structure CHS, a contact area between the bit line BL and the channel structure CHS may be increase, and because the contact plug 130 is in contact with and connected to the channel pad portion CHD of the channel structure CHS, a contact area between the contact plug 130 and the channel structure CHS may be increased, so that ON current characteristics may be improved, and thus the electrical characteristics of the semiconductor memory device 1 may be improved.

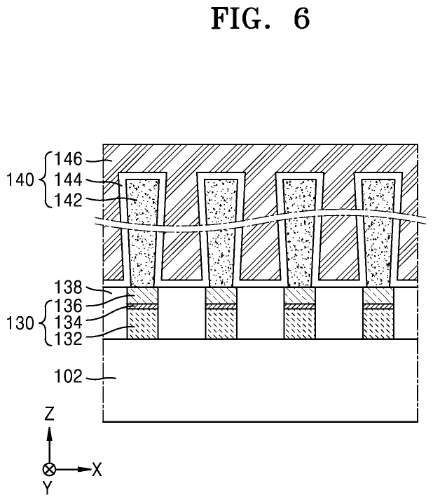

In addition, as described with reference to FIGS. 6 to 17, because the capacitors 140 are formed at a relatively high process temperature before the channel structures CHS, a thermal budget applied to the channel structures CHS may be reduced, and thus, even if the channel structures CHS are formed with a material having relatively low thermal stability, the electrical characteristics of the channel structures CHS may be maintained, thereby improving the operational reliability of the semiconductor memory device 1.

Also, because each of the lowermost ends of the word lines WL may be located at substantially the same vertical level as, or slightly higher or lower than, the channel structures CHS and the lowermost ends of the channel extension portions CHE of the channel structures CHS, the area in which the word lines WL and the channel structures CHS overlap may increase, so that the operating performance of the vertical channel transistors may be improved, and thus the operating performance of the semiconductor memory device 1 may be improved.

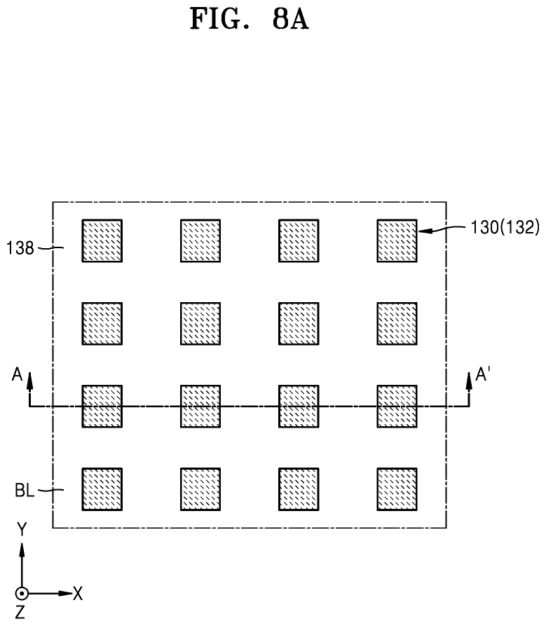

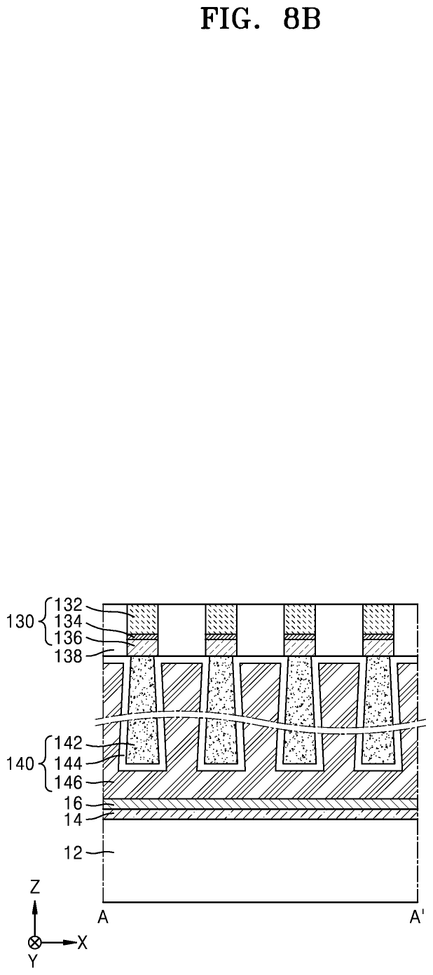

FIGS. 6 to 17 are cross-sectional views and plan views illustrating a method of manufacturing a semiconductor memory device according to embodiments. In detail, FIGS. 6, 7, 8B, 9B, 10B, 11B, 12B, 13B, 14B, 15B, 16, and 17 are cross-sectional views illustrating a method of manufacturing a semiconductor memory device according to embodiments and are cross-sectional views corresponding to a cross-section taken along a line A-A′ of FIG. 4, and FIGS. 8A, 9A, 10A, 11A, 12A, 13A, 14A, and 15A are plan views illustrating a method of manufacturing a semiconductor memory device according to embodiments, in which some components or portions of some components may be omitted for convenience of illustration.

Referring to FIG. 6, the contact plugs 130 and the second interlayer insulating layer 138 surrounding the contact plugs 130 are formed on a base substrate 102. The contact plugs 130 may pass through the second interlayer insulating layer 138. In some embodiments, each of the contact plugs 130 may include the first conductive pattern 132, the second conductive pattern 134, and the third conductive pattern 136 sequentially stacked on the base substrate 102. The contact plugs 130 may be formed to be arranged in a matrix arrangement to be apart from each other in the first horizontal direction (the X direction) and the second horizontal direction (the Y direction).

Thereafter, the capacitors 140 are formed on the contact plugs 130 and the second interlayer insulating layer 138. The capacitors 140 may include the lower electrodes 142 connected to the contact plugs 130, the capacitor dielectric film 144 conformally covering the surface of each of the lower electrodes 142, and the upper electrode 146 covering the lower electrodes 142 with the capacitor dielectric film 144 therebetween. Each of the lower electrodes 142 may be formed to be connected to the third conductive pattern 136 included in each of the contact plugs 130. In some embodiments, the lower electrodes 142 may be formed to be arranged in a matrix form in a row in each of the first horizontal direction (the X direction) and the second horizontal direction (the Y direction). In some other embodiments, the lower electrodes 1420 may be formed to be arranged in a honeycomb shape in a zigzag manner with respect to the first horizontal direction (the X direction) or the second horizontal direction (the Y direction).

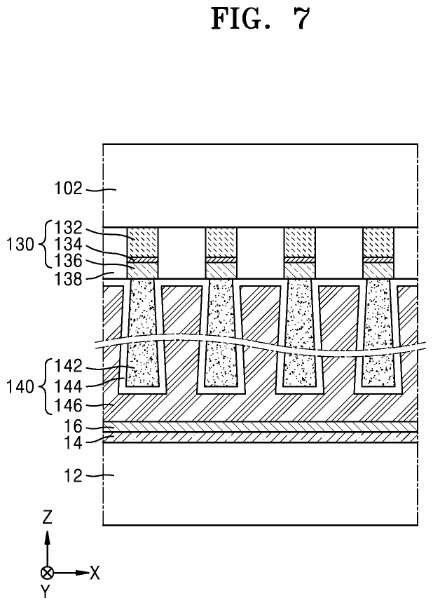

Referring to FIG. 7, after forming an upper adhesive layer 16 covering the upper electrode 146, the resultant structure of FIG. 6 with the upper adhesive layer 16 is turned over and attached to a carrier substrate 12 to which a lower adhesive layer 14 is attached. The upper adhesive layer 16 and the lower adhesive layer 14 are in contact with each other, and the base substrate 102 may face upwards. In some embodiments, one of the lower adhesive layer 14 and the upper adhesive layer 16 may not be formed, and the upper electrode 146 may be attached to the carrier substrate 12 by one of the lower adhesive layer 14 and the upper adhesive layer 16.

Referring to FIGS. 7 and 8 together, the base substrate 102 is removed to expose the contact plugs 130 and the second interlayer insulating layer 138. For example, the base substrate 102 may be removed so that the first conductive patterns 132 and the second interlayer insulating layer 138 of the contact plugs 130 may be exposed.

Referring to FIGS. 9A and 9B together, the mold structures MOL are formed on the contact plugs 130 and the second interlayer insulating layer 138. The mold structures MOL may be formed to be elongated in the second horizontal direction (the Y direction) and repeatedly arranged to be apart from each other in the first horizontal direction (the X direction).

The mold structures MOL may be formed to cover a portion of each of the contact plugs 130 but not cover the remaining portions. For example, the mold structures MOL may be formed to cover a portion of each of the contact plugs 130 included in a pair of rows adjacent in the first horizontal direction (the X direction) among the contact plugs 130 arranged to be apart from each other in the second horizontal direction (the Y direction) and forming a plurality of rows, but not to cover the remaining portion.

In some embodiments, each of the mold structures MOL may be formed to have a stacked structure of a first mold layer MOL1 and a second mold layer MOL2. For example, the first mold layer MOL1 and the second mold layer MOL2 may be sequentially formed on the contact plugs 130 and the second interlayer insulating layer 138.

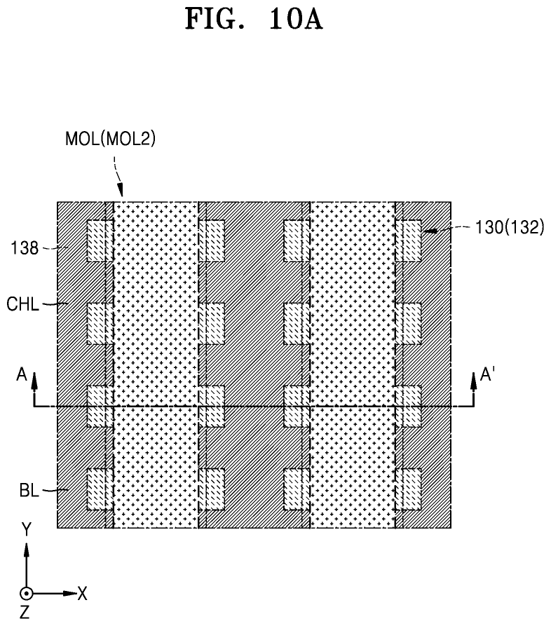

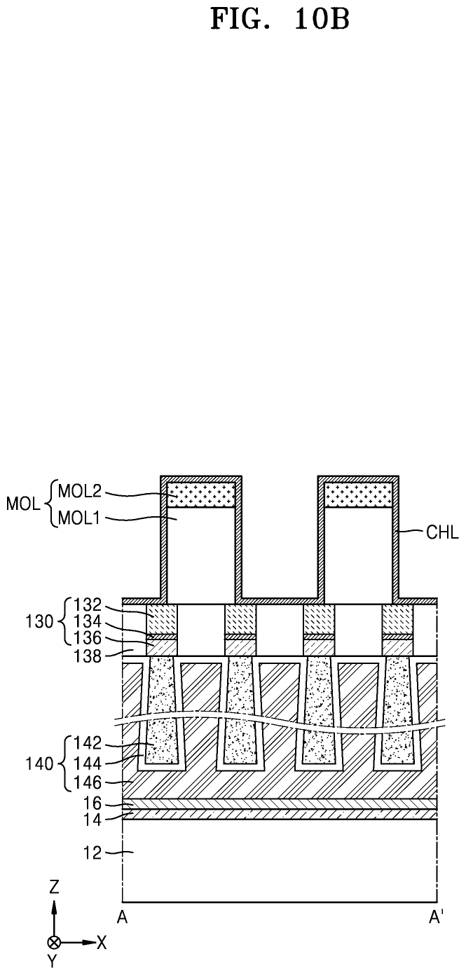

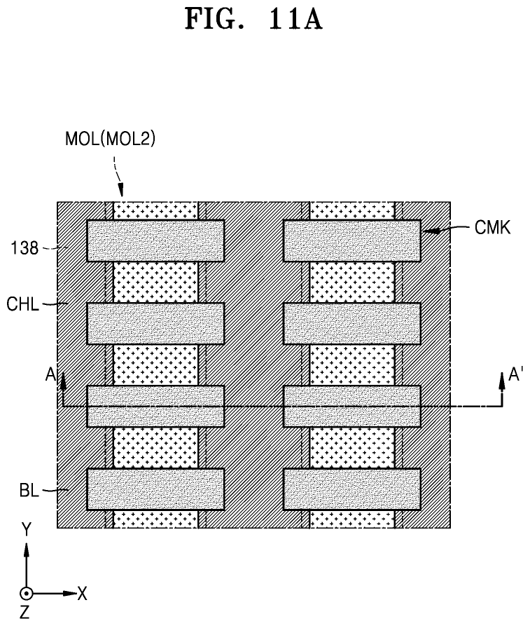

Referring to FIGS. 10A and 10B together, the channel material layer CHL is formed on the contact plugs 130, the second interlayer insulating layer 138, and the mold structures MOL. In some embodiments, the channel material layer CHL may be formed to conformally cover the surfaces of the contact plugs 130, the second interlayer insulating layer 138, and the mold structures MOL.

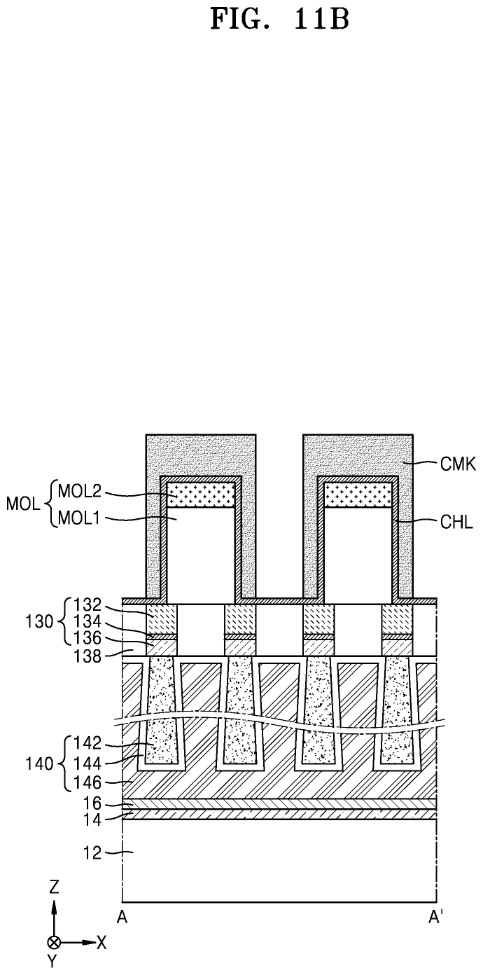

Referring to FIGS. 11A and 11B together, a plurality of mask patterns CMK are formed on the channel material layer CHL. Each of the mask patterns CMK may be formed to cross the mold structure MOL in the first horizontal direction (the X direction) planarly. Each of the mask patterns CMK may be formed to overlap a pair of contact plugs 130, which are adjacent to each other in the first horizontal direction (the X direction), in the vertical direction (the Z direction). For example, each of the mask patterns CMK may be formed to overlap a pair of contact plugs 130, which are partially covered by one mold layer MOL and adjacent to each other in the first horizontal direction (the X direction), in the vertical direction (the Z direction) and cross one mold layer MOL to cover a portion of one mold layer MOL covering a portion of each of a pair of contact plugs 130, e.g., portions of both sidewalls of one mold layer MOL and a portion of an upper surface of one mold layer MOL.

Referring to FIGS. 11A and 11B, and FIGS. 12A and 12B together, the channel material layer CHL may be patterned using the mask patterns CMK as etching masks to form a plurality of channel structures CHS. Each of the channel structures CHS may be formed to include the channel pad portion CHD, the channel extension portion CHE, and the channel pattern CHP located between the channel pad portion CHD and the channel extension portion CHE.

A pair of channel structures CHS among the channel structures CHS may be formed integrally. The channel pad portion CHD, the channel pattern CHP, and the channel extension portion CHE included in each of the channel structures CHS may be formed integrally. The channel pad portion CHD may cover a portion of the contact plug 130 that is not covered by the mold structure MOL, the channel pattern CHP may cover a portion of one sidewall of the mold structure MOL, and the channel extension portion CHE may cover a portion of an upper surface of the mold structure MOL. Each of the channel pad portion CHD, the channel pattern CHP, and the channel extension portion CHE included in each of the channel structures CHS may have substantially the same horizontal width in the second horizontal direction (the Y direction). Each of the channel structures CHS may be formed such that the channel pad portion CHD is in contact with a portion of the contact plug 130, the channel pattern CHP extends along one sidewall of the mold structure MOL and extends to the upper surface of the mold structure MOL so that the channel extension portion CHE covers a portion of the upper surface of the mold structure MOL.

A pair of channel structures CHS that are adjacent in the first horizontal direction (the X direction) and cover one mold structure MOL, among the channel structures CHS, may share the channel extension portion CHE and form an integral body. Each of a pair of channel pad portions CHD, a pair of channel patterns CHP, and a shared channel extension portion CHE included in a pair of channel structures CHS forming an integral body may have substantially the same horizontal width in the second horizontal direction (the Y direction). A pair of channel structures CHS forming an integral body may be formed to overlap a pair of contact plugs 130, which is adjacent in the first horizontal direction (the X direction), in the vertical direction (the Z direction). For example, each of the channel structures CHS may be formed to cover remaining portions not covered by one mold layer MOL among a pair of contact plugs 130 respectively partially covered by one mold layer MOL and adjacent in the first horizontal direction (the X direction) and cover a portion of one mold layer MOL covering a portion of each of a pair of contact plugs 130, for example, a portion of both sidewalls of one mold layer MOL and a portion of an upper surface of one mold layer MOL.

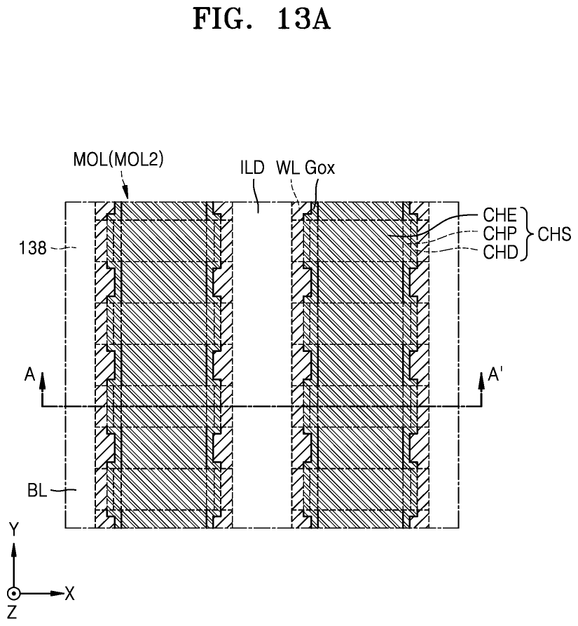

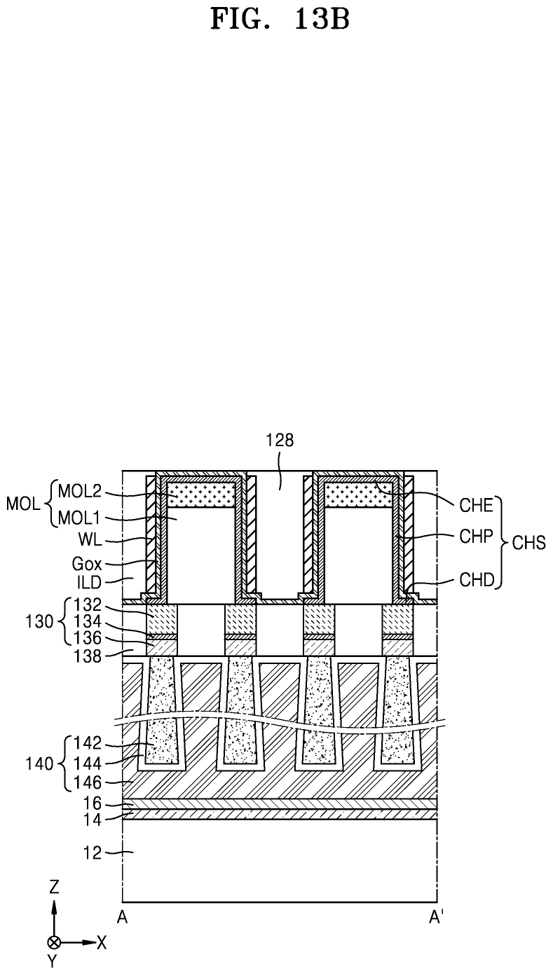

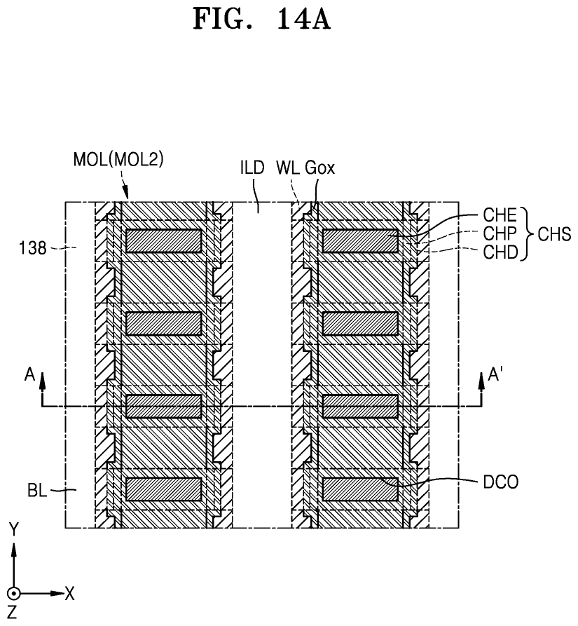

Referring to FIGS. 13A and 13B together, the gate dielectric films Gox are formed to cover the channel structures CHS, and the word lines WL are formed to cover the channel structures CHS with the gate dielectric films Gox therebetween.

In some embodiments, the gate dielectric films Gox may be integrally formed to conformally cover the exposed surfaces of each of the channel structures CHS and the second interlayer insulating layer 138. For example, the gate dielectric films Gox may cover the channel pad portion CHD, the channel pattern CHP, and the channel extension portion CHE of the channel structures CHS and may cover portions of the upper surface of the second interlayer insulating layer 138 exposed between the channel structures CHS. Even if the gate dielectric films Gox are integrally formed, portions of the gate dielectric films Gox covering portions of the upper surface of the second interlayer insulating layer 138 do not function as dielectric films of the capacitor (140 of FIG. 5), and therefore, each of the gate dielectric films Gox may be a portion covering the channel pad portion CHD, the channel pattern CHP, and the channel extension portion CHE of each of the channel structures CHS.

Each of the word lines WL may face the channel pattern CHP of the corresponding channel structure CHS with the gate dielectric film Gox therebetween. The inner wall of each of the word lines WL may face the corresponding channel pattern CHP. The word lines WL may be formed to have a spacer shape respectively covering both sidewalls of the mold structures MOL in the first horizontal direction (the X direction). For example, the word lines WL may be formed by forming a word line material layer that conformally covers the gate dielectric films Gox and then anisotropically etching the word line material layer. Each of the word lines WL may be formed such that the uppermost end of each of the word lines WL is located at a vertical level lower than the uppermost end of the gate dielectric film Gox. In some embodiments, each of the word lines WL may be formed such that the uppermost end of each of the word lines WL is located at a vertical level higher than the upper surface of the mold structures MOL. In some embodiments, each of the lowermost end of the word lines WL may be located at a substantially same vertical level as the uppermost end of the channel structures CHS, for example, the upper surface of the channel extension portion CHE, but is not limited thereto. For example, each of the uppermost ends of the word lines WL may be located at a vertical level that is somewhat higher or somewhat lower than the upper surface of the channel extension portion CHE.

Thereafter, the insulating patterns 128 are formed to cover a portion of the gate dielectric films Gox and the word lines WL and fill the space between the mold structures MOL. The insulating patterns 128 may be formed by forming an insulating material layer that covers the gate dielectric films Gox and the word lines WL and fills the space between the mold structures MOL and then removing a portion of the insulating material layer that is located at a vertical level higher than that of the uppermost surfaces of the gate dielectric films Gox. The uppermost surfaces of the gate dielectric films Gox may be exposed without being covered by the insulating patterns 128. Because the uppermost end of each of the word lines WL is located at a vertical level lower than that of the uppermost end of the gate dielectric film Gox, the uppermost end of each of the word lines WL may be covered by the insulating pattern 128 and may not be exposed to the outside. For example, the outer wall and upper surface of each of the word lines WL may be covered with the insulating pattern 128 and the inner wall and lower surface of each of the word lines WL may be covered with the gate dielectric film Gox, so that each of the word lines WL may be surrounded by the insulating pattern 128 and the gate dielectric film Gox.

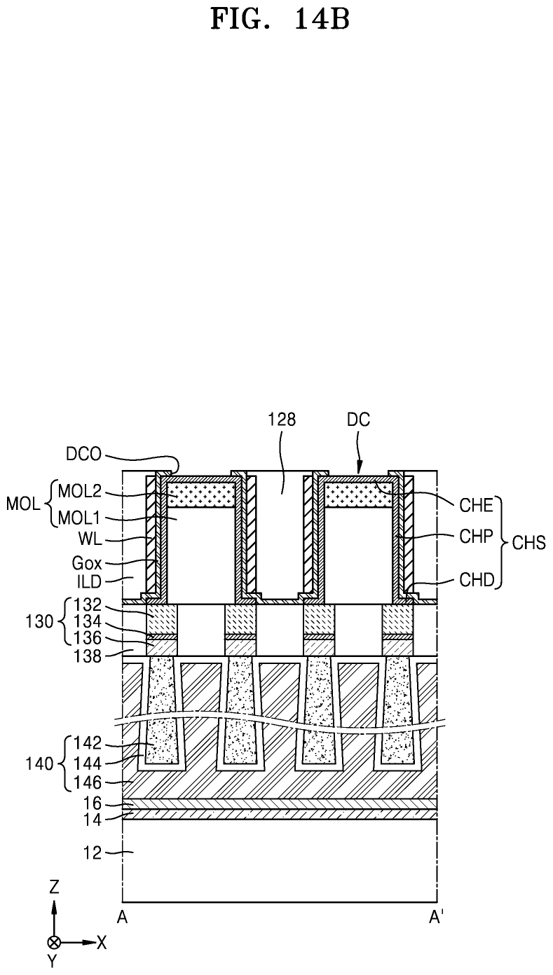

Referring to FIGS. 14A and 14B together, portions of the gate dielectric films Gox are removed to form the holes DCO. The holes DCO may be formed to pass through the gate dielectric films Gox to expose the channel extension portion CHE of the channel structures CHS at the bottom thereof. The holes DCO may be formed to be repeatedly arranged apart from each other in the first horizontal direction (the X direction) and the second horizontal direction (the Y direction).

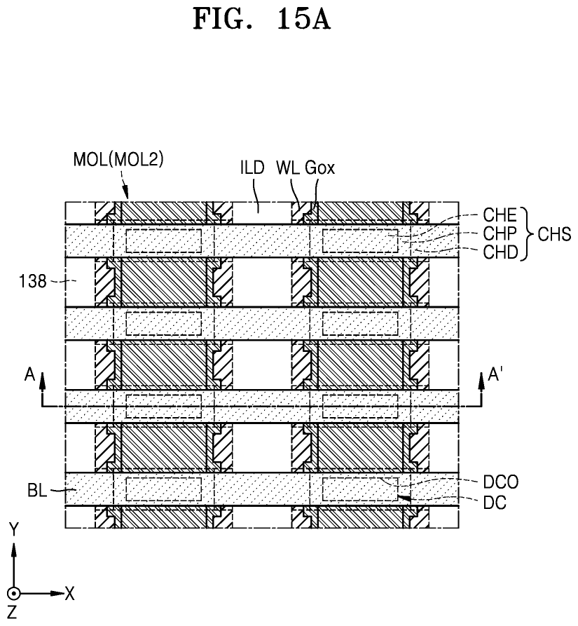

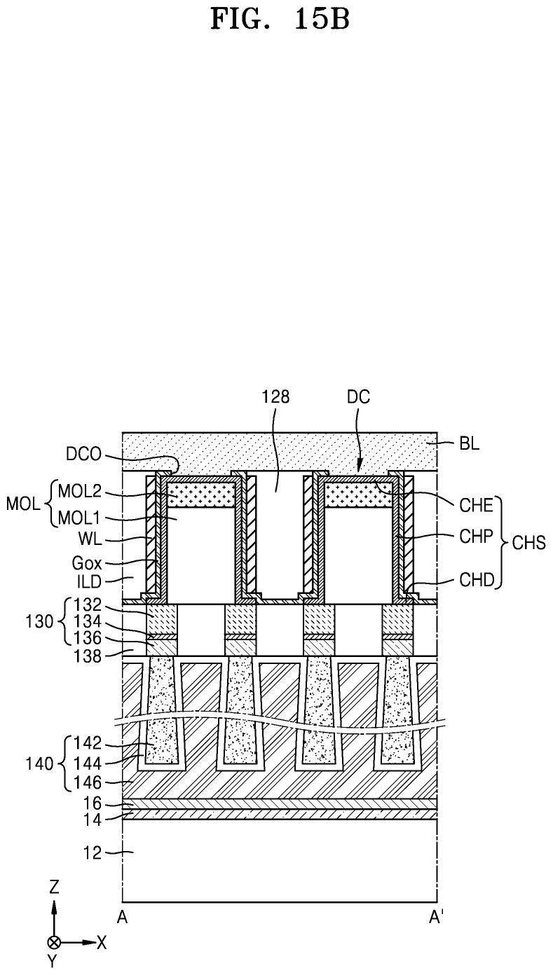

Referring to FIGS. 15A and 15B together, the bit lines BL are formed to be elongated in the first horizontal direction (the X direction) and are repeatedly arranged apart from each other in the second horizontal direction (the Y direction) on the insulating patterns 128 and the channel extension portion CHE of the channel structures CHS. The bit lines BL may be formed to fill the holes DCO and contact the channel extension portion CHE of the channel structures CHS. Portions of the bit lines BL that fill the holes DCO may be contacts DC. The contacts DC may be portions of the bit lines BL that protrude toward the channel structures CHS. For example, the contacts DC may be portions that protrude downwards from the bit lines BL. The contacts DC may pass through the gate dielectric films Gox and be connected to the channel extension portion CHE of the channel structures CHS.

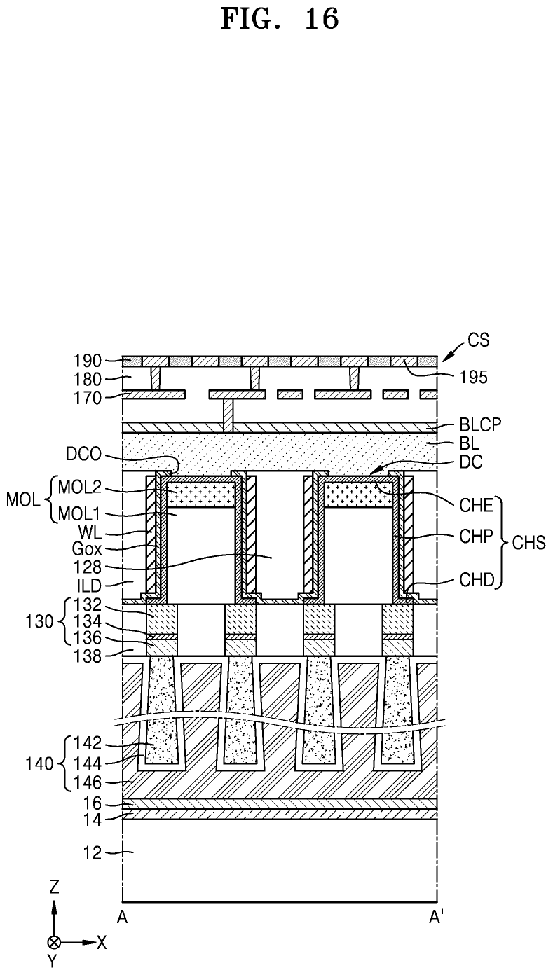

Referring to FIG. 16, after the insulating capping lines BLCP covering the bit lines BL are formed, the first interlayer insulating layer (OBL of FIG. 4) filling a space between the bit lines BL is formed as shown in FIG. 4.

Thereafter, the cell interconnection structure 170 and the inter-cell interconnection insulating layer 180 surrounding the cell interconnection structure 170 may be formed on the insulating capping lines BLCP and the first interlayer insulating layer (OBL of FIG. 4), thereby forming the cell array structure CS. The cell interconnection structure 170 may include the cell interconnection lines and the cell interconnection contacts. In some embodiments, some of the cell interconnection contacts of the cell interconnection structure 170 may be formed to pass through at least some of the insulating capping lines BLCP to be connected to at least some of the bit lines BL.

On the cell array structure CS, a plurality of upper metal pads 195 electrically connected to the cell interconnection structure 170 and a first bonding insulating layer 190 surrounding the upper metal pads 195 may be formed. The upper metal pads 195 and the first bonding insulating layer 190 may be formed on the cell interconnection structure 170 and the inter-cell interconnection insulating layer 180.

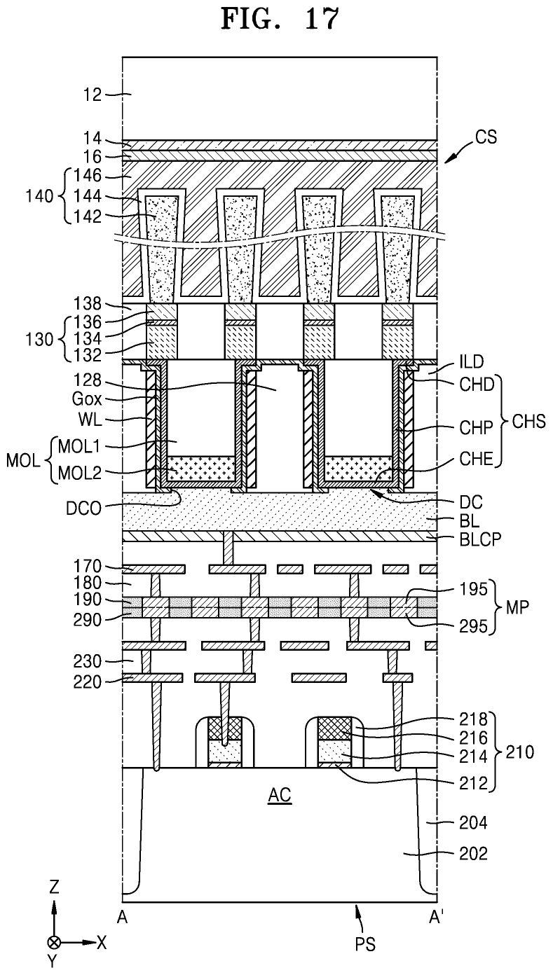

Referring to FIG. 17, after forming the peripheral circuit structure PS, the lower metal pads 295 electrically connected to the peripheral circuit interconnection structure 220 and the second bonding insulating layer 290 surrounding the lower metal pads 295 are formed on the peripheral circuit structure PS. The peripheral circuit structure PS may be formed to include the peripheral circuit substrate 202 having the active regions AC defined by circuit device separator 204, the circuit gate structures 210 arranged in the active regions AC of the peripheral circuit substrate 202, the peripheral circuit interconnection structure 220 electrically connected to the active regions AC and/or the circuit gate structures 210, and the inter-peripheral circuit interconnection insulating layer 230 covering the circuit gate structures 210 on the peripheral circuit substrate 202 and surrounding the peripheral circuit interconnection structure 220.

Thereafter, the cell array structure CS formed with the upper metal pads 195 and the first bonding insulating layer 190, which is a resultant structure of FIG. 16, is turned over and attached onto the peripheral circuit structure PS formed with the lower metal pads 295 and the second bonding insulating layer 290. The first bonding insulating layer 190 and the second bonding insulating layer 290 may be in contact with and bonded to each other by forming a covalent bond. The upper metal pads 195 and the lower metal pads 295 corresponding to each other may be expanded by heat to come into contact with each other to become the bonding pads MP that are diffusion bonded to form an integrated body through diffusion of the metal atoms contained therein.

Thereafter, the carrier substrate 12, the lower adhesive layer 14, and the upper adhesive layer 16 may be removed, thereby forming the semiconductor memory device 1 as shown in FIG. 5. In some embodiments, after removing the carrier substrate 12, the lower adhesive layer 14, and the upper adhesive layer 16, an interconnection structure may be further formed to electrically connect the capacitors 140 to the peripheral circuit interconnection structure 220 or to electrically connect the peripheral circuit interconnection structure 220 to the outside.

Referring to FIGS. 4 to 17 together, because the capacitors 140, which are formed at a relatively high process temperature, are formed before the channel structures CHS, a heat budget applied to the channel structures CHS may be reduced, so that even if the channel structures CHS are formed with a material having relatively low thermal stability, the electrical characteristics of the channel structures CHS may be maintained, thereby improving the operational reliability of the semiconductor memory device 1.

In addition, because the word lines WL and the channel structures CHS may be formed to increase an overlapping region with each other, the operating performance of the vertical channel transistors may be improved, and because the contact plug 130 and the channel structure CHS may be formed to increase a contact area, the ON current characteristics may be improved, thereby improving the operating performance and electrical characteristics of the semiconductor memory device 1.

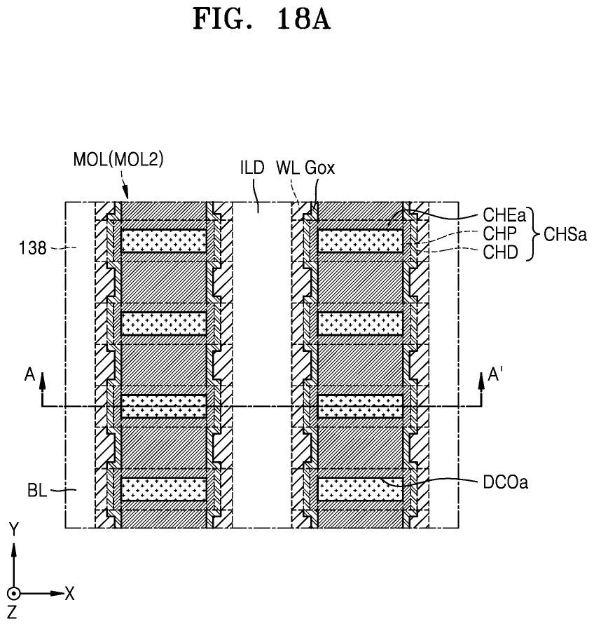

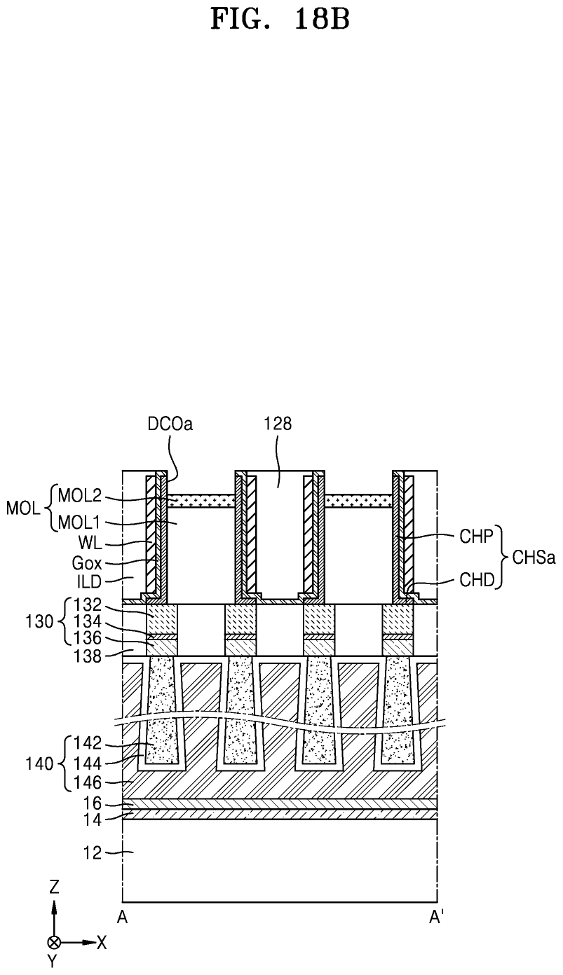

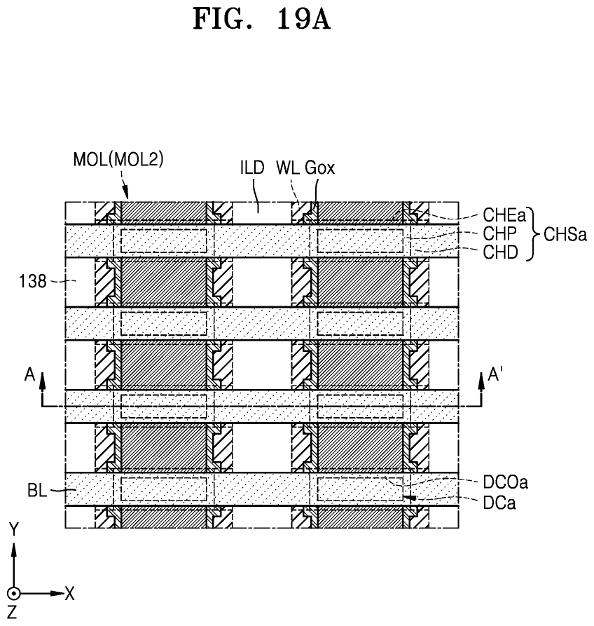

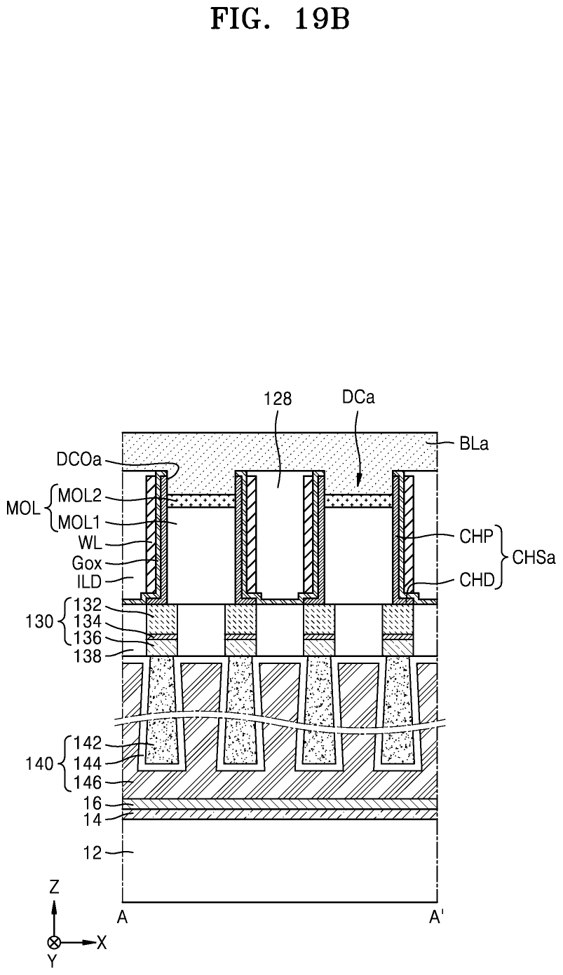

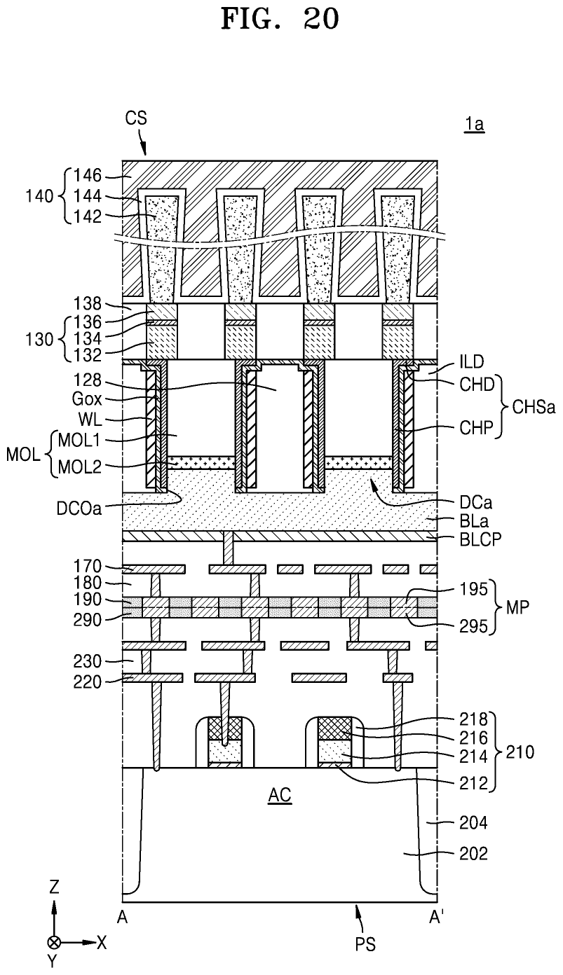

FIGS. 18A to 19B are cross-sectional views illustrating a method of manufacturing a semiconductor memory device according to embodiments, and FIG. 20 is a cross-sectional view of a semiconductor memory device la according to embodiments. In detail, FIGS. 18A to 20 are cross-sectional views taken along line A-A′ of FIG. 4.

Referring to FIGS. 18A and 18B together, after forming the gate dielectric films Gox, the word lines WL, and the insulating patterns 128 as shown in FIGS. 13A and 13B, portions of the gate dielectric films Gox, the channel extension portion (CHE of FIGS. 13A and 13B) of the channel structures (CHS of FIGS. 13A and 13B), and portions of the mold structures MOL are removed to form a plurality of holes DCOa.

The channel structures (CHS of FIGS. 13A and 13B), each including the channel extension portion (CHE of FIGS. 13A and 13B), the channel pattern CHP, and the channel pad portion CHD, may be members of a plurality of channel structures CHSa, with each including a channel extension portion CHEa, a channel pattern CHP, and a channel pad portion CHD penetrated by each of the holes DCOa.

The holes DCOa may be formed to pass through the gate dielectric films Gox and the channel extension portion CHEa of the channel structures CHSa to expose the second mold layer MOL2 of the mold structures MOL at the bottom. In the process of forming the holes DCOa, an upper portion of the second mold layer MOL2 of the mold structures MOL may be removed, so that an upper portion of the channel pattern CHP of the channel structures CHSa may be exposed on an inner surface of the holes DCOa. For example, on the inner surface of the holes DCOa, an upper portion of one of both sidewalls of the channel pattern CHP of the channel structures CHSa facing the mold structures MOL in the first horizontal direction (the X direction) may be exposed. In some embodiments, a channel extension portion CHEa of the channel structures CHSa may be exposed on an upper portion of the inner surface of the holes DCOa. For example, within the holes DCOa, a portion of the channel extension portion CHEa of the channel structures CHSa and a portion of the channel pattern CHP may be exposed together.

Referring to FIGS. 19A and 19B together, a plurality of bit lines BLa, filling the holes DCOa, extending in the first horizontal direction (the X direction), and repeatedly arranged to be apart from each other in the second horizontal direction (the Y direction) are formed on the insulating patterns 128. The bit lines BLa may be formed to fill the holes DCOa and contact the channel pattern CHP and the channel extension portion CHEa of the channel structures CHSa. Portions of the bit lines BLa filling the holes DCOa may be the contacts DCa. The contacts DCa may be portions of the bit lines BLa protruding toward the channel structures CHSa. For example, the contacts DCa may be portions that protrude downwards from the bit lines BLa. The contacts DCa may penetrate through the gate dielectric films Gox and the channel extension portion CHEa of the channel structures CHSa and may be connected to the channel extension portion CHEa and the channel pattern CHP of the channel structures CHSa.

Referring to FIG. 20, after the insulating capping lines BLCP, the first interlayer insulating layer (OBL of FIG. 4), the cell interconnection structure 170, and the inter-cell interconnection insulating layer 180 are formed to form the cell array structure CS as shown in FIG. 16, the upper metal pads 195 and the first bonding insulating layer 190 are formed on the cell array structure CS, the lower metal pads 295 and the second bonding insulating layer 290 are formed on the peripheral circuit structure PS and as shown in FIG. 17, the first bonding insulating layer 190 and the second bonding insulating layer 290 are brought into contact with each other, the upper metal pads 195 and the lower metal pads 295 corresponding to each other are brought into contact with each other to form the bonding pads MP, and then the carrier substrate 12, the lower adhesive layer 14, and the upper adhesive layer 16 are removed, thereby forming the semiconductor memory device 1a.

Each of the lowermost ends of the word lines WL may be located at a vertical level that is lower than the lowermost ends of the mold structures MOL (i.e., lower surfaces of the mold structures MOL) and higher than the lowermost ends of the gate dielectric films Gox and may be located at a vertical level that is lower than the upper surfaces of the contacts DCa.

In the semiconductor memory device 1a according to the inventive concept, because the contacts DCa of the bit lines BLa are in contact with and connected to a lower portion of one sidewall of the channel pattern CHP of the channel structures CHSa and a portion of the channel extension portion CHEa, a contact area between the bit lines BLa and the channel structures CHSa may be increased, so that the electrical characteristics of the semiconductor memory device 1a may be improved.

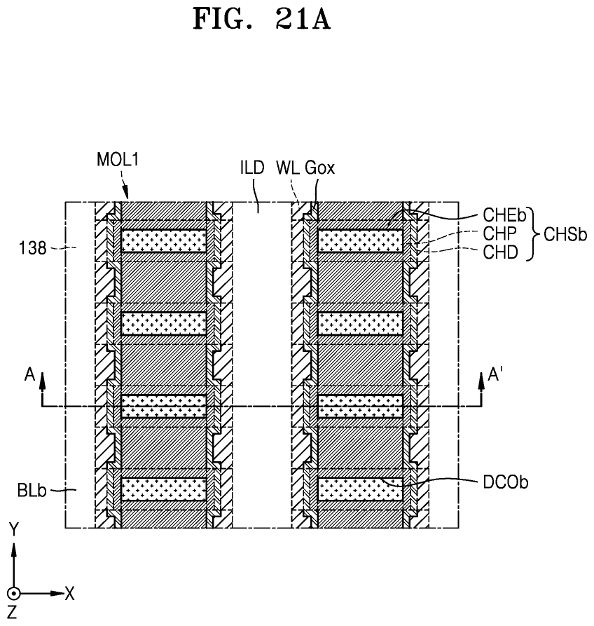

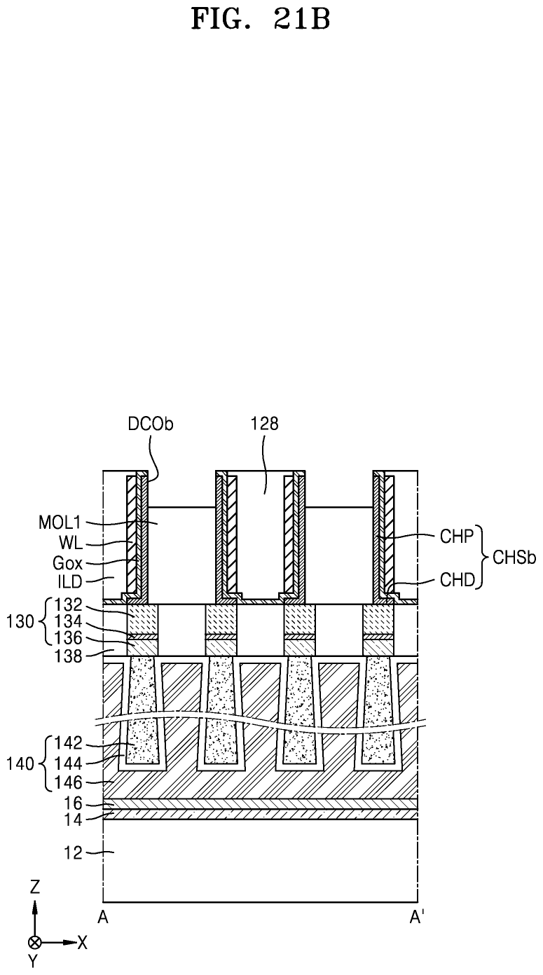

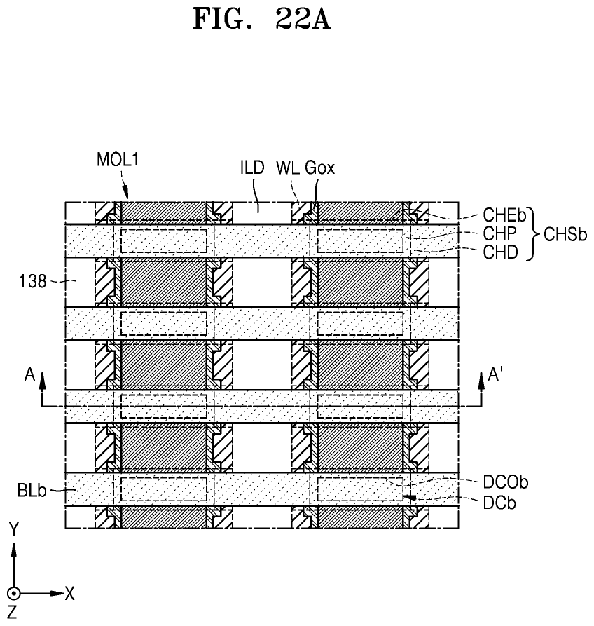

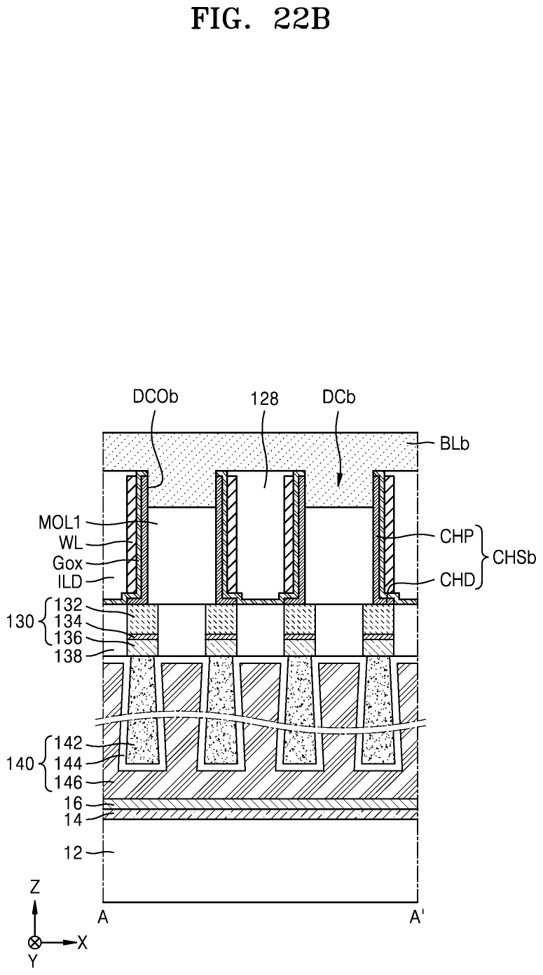

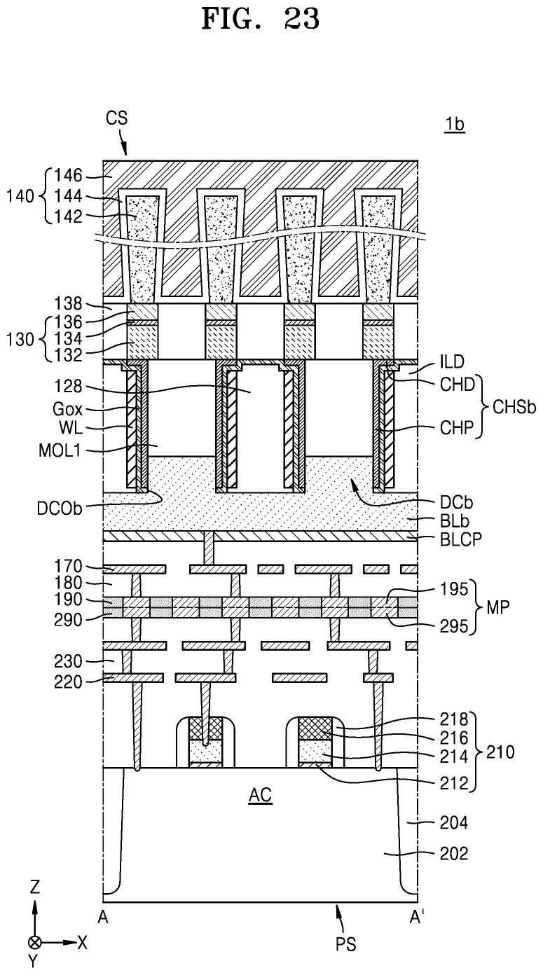

FIGS. 21A to 22B are cross-sectional views illustrating a method of manufacturing a semiconductor memory device according to embodiments, and FIG. 23 is a cross-sectional view of a semiconductor memory device according to embodiments. In detail, FIGS. 21A to 23 are cross-sectional views taken along lines A-A′ of FIG. 4.

Referring to FIGS. 21A and 21B together, after forming the gate dielectric films Gox, the word lines WL, and the insulating patterns 128 as shown in FIGS. 13A and 13B, portions of the gate dielectric films Gox, the channel extension portion (CHE of FIGS. 13A and 13B) of the channel structures (CHS of FIGS. 13A and 13B), and portions of the mold structures MOL are removed to form the holes DCOa. The channel structures CHSb, each including a channel extension portion CHEb, the channel pattern CHP, and the channel pad portion CHD penetrated by a plurality of holes DCOb, may be the same as the channel structures (CHS) of FIGS. 13A and 13B, each including the channel extension portion (CHE of FIGS. 13A and 13B), the channel pattern CHP, and the channel pad portion CHD, respectively. The channel structures CHSb, each including the channel extension portion CHEb, the channel pattern CHP, and the channel pad portion CHD, may be substantially the same as or the same as the channel structures CHSa, each including the channel extension portion CHEa, the channel pattern CHP, and the channel pad portion CHD, shown in FIGS. 18A to 20, and thus, description that may be redundant description may be omitted.

The holes DCOb may be formed to pass through the gate dielectric films Gox and the channel extension portion CHEb of the channel structures CHSb to expose the first mold layer MOL1 of the mold structures MOL at the bottom. In the process of forming the holes DCOb, the second mold layer (MOL2 of FIGS. 13A and 13B) of the mold structures MOL may be completely removed, and an upper portion of the channel pattern CHP of the channel structures CHSb may be exposed from the inner surface of the holes DCOb. In some embodiments, the channel extension portion CHEb of the channel structures CHSb may be exposed from an upper portion of the inner surface of the holes DCOb. For example, a portion of a channel extension portion CHEb of the channel structures CHSb and a portion of the channel pattern CHP may be exposed together within the holes DCOb.

Referring to FIGS. 22A and 22B together, a plurality of bit lines BLb, filling the holes DCOb, extending in the first horizontal direction (the X direction), and repeatedly arranged apart from each other in the second horizontal direction (the Y direction), are formed on the insulating patterns 128. The bit lines BLb may be formed to fill the holes DCOb and contact the channel pattern CHP and the channel extension portion CHEb of the channel structures CHSb. Portions of the bit lines BLb that fill the holes DCOb may be contacts DCb. The contacts DCb may be portions of the bit lines BLb that protrude toward the channel structures CHSb. For example, the contacts DCb may be portions that protrude downwards from the bit lines BLb. The contacts DCb may pass through the gate dielectric films Gox and the channel extension portions CHEb of the channel structures CHSb and may be connected to the channel extension portions CHEb and the channel patterns CHP of the channel structures CHSb.

Referring to FIG. 23, after the insulating capping lines BLCP, the first interlayer insulating layer (OBL of FIG. 4), the cell interconnection structure 170, and the inter-cell interconnection insulating layer 180 are formed to form the cell array structure CS as shown in FIG. 16, the upper metal pads 195 and the first bonding insulating layer 190 are formed on the cell array structure CS, the lower metal pads 295 and the second bonding insulating layer 290 are formed on the peripheral circuit structure PS and as shown in FIG. 17, the first bonding insulating layer 190 and the second bonding insulating layer 290 are brought into contact with each other, the upper metal pads 195 and the lower metal pads 295 corresponding to each other are brought into contact with each other to form the bonding pads MP, and then the carrier substrate 12, the lower adhesive layer 14, and the upper adhesive layer 16 are removed, thereby forming the semiconductor memory device 1b.

Each of the lowermost ends of the word lines WL may be located at a vertical level that is lower than the lowermost ends of the mold structures MOL (i.e., lower surfaces of the mold layers MOL1) and higher than the lowermost ends of the gate dielectric films Gox and may be located at a vertical level that is lower than the upper surfaces of the contacts DCb.

In the semiconductor memory device 1b according to the inventive concept, because the contacts DCb of the bit lines BLa are in contact with and connected to a lower portion of one sidewall of the channel pattern CHP of the channel structures CHSb and a portion of the channel extension portion CHEb, a contact area between the bit lines BLb and the channel structures CHSb may be increased, so that the electrical characteristics of the semiconductor memory device 1b may be improved.

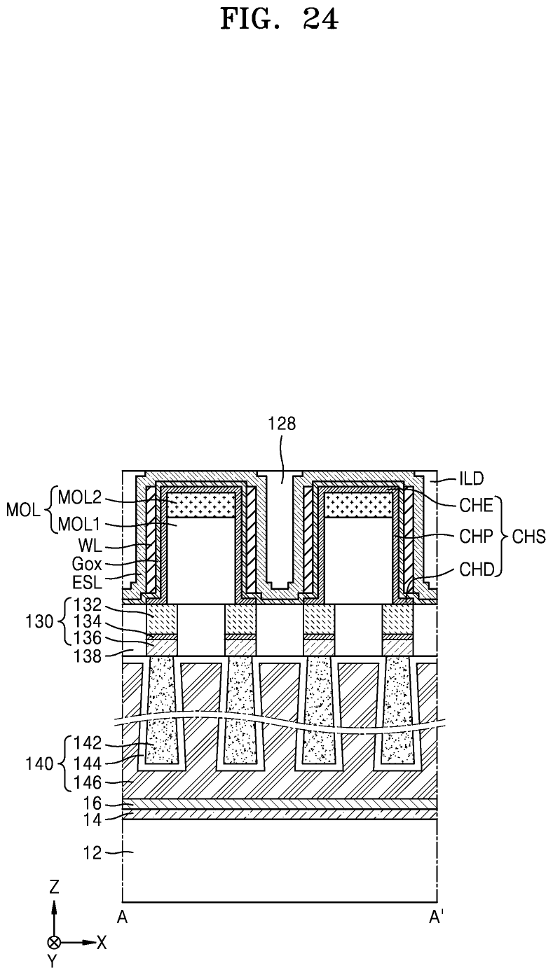

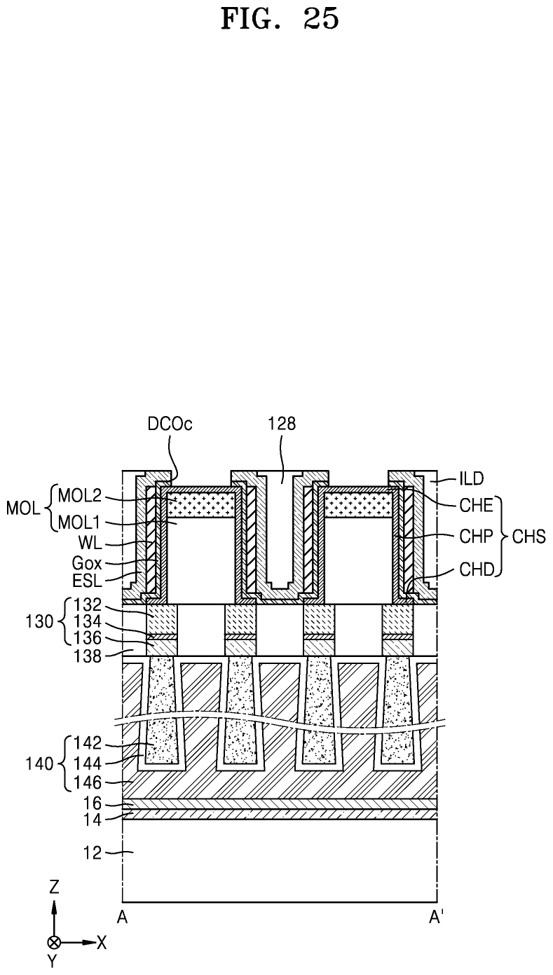

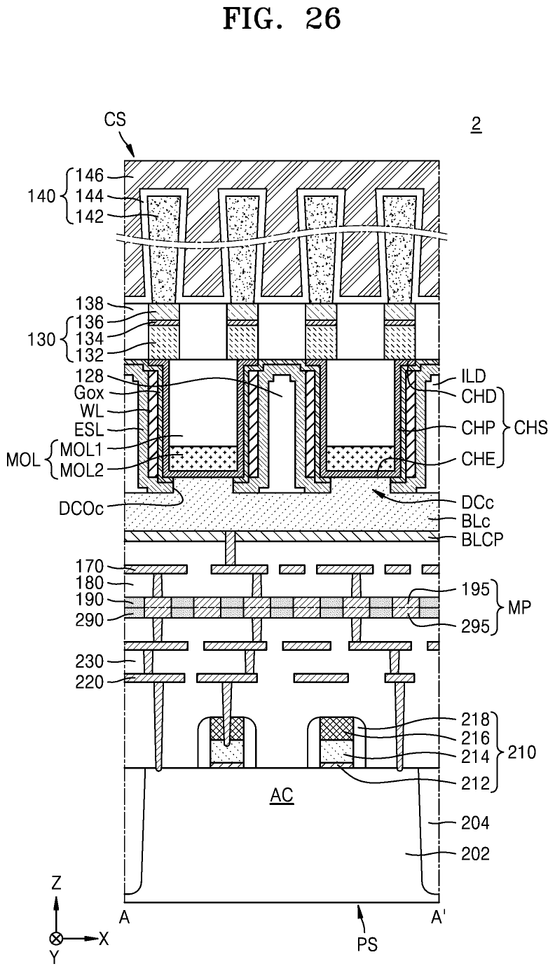

FIGS. 24 and 25 are cross-sectional views illustrating a method of manufacturing a semiconductor memory device according to embodiments, and FIG. 26 is a cross-sectional view of a semiconductor memory device according to embodiments. In detail, FIGS. 24 to 26 are cross-sectional views taken along line A-A′ of FIG. 4.

Referring to FIG. 24, after forming the channel structures CHS as shown in FIGS. 12A and 12B, the gate dielectric films Gox covering the channel structures CHS are formed and the word lines WL covering the channel structures CHS are formed with the gate dielectric films Gox therebetween.

Thereafter, an etch stop layer ESL covering the gate dielectric films Gox and the word lines WL may be formed. The etch stop layer ESL may be formed to conformally cover the surfaces of the gate dielectric films Gox and the word lines WL. The etch stop layer ESL may include silicon nitride. Thereafter, the insulating patterns 128 are formed to cover the etch stop layer ESL and fill the space between the mold structures MOL. The insulating patterns 128 may be formed by forming an insulating material layer that covers the etch stop layer ESL and fills the space between the mold structures MOL and then removing a portion of the insulating material layer that is located at a vertical level higher than the uppermost surface of the etch stop layer ESL. The uppermost surface of the etch stop layer ESL may be exposed without being covered by the insulating patterns 128. Because the uppermost end of each of the word lines WL is located at a vertical level lower than the uppermost end of the gate dielectric film Gox, the uppermost end of each of the word lines WL may be covered by the etch stop layer ESL and the insulating pattern 128 and not be exposed to the outside. For example, the outer wall and upper surface of each of the word lines WL may be covered with the etch stop layer ESL, the inner wall and lower surface of each of the word lines WL may be covered with the gate dielectric film Gox, so that each of the word lines WL may be surrounded by the etch stop layer ESL and the gate dielectric film Gox.

Referring to FIG. 25, portions of the etch stop layer ESL and portions of the gate dielectric films Gox are removed to form a plurality of holes DCOc. The holes DCOc may be formed to pass through the etch stop layer ESL and the gate dielectric films Gox to expose the channel extension portion CHE of the channel structures CHS at the bottom. The holes DCOc may be formed to be repeatedly arranged apart from each other in the first horizontal direction (the X direction) and the second horizontal direction (the Y direction).

Referring to FIGS. 25 and 26 together, a plurality of bit lines BLc, which fill the holes DCOc, extend in the first horizontal direction (the X direction), and repeatedly arranged to be apart from each other in the second horizontal direction (the Y direction), are formed on the etch stop layer ESL and the insulating patterns 128. The bit lines BLc may be formed to fill the holes DCOc to contact the channel extension portion CHE of the channel structures CHS. Portions of the bit lines BLc that fill the holes DCOc may be the contacts DCc. The contacts DCc may be portions of the bit lines BLc that protrude toward the channel structures CHS. The contacts DCc may pass through the etch stop layer ESL and the gate dielectric films Gox and may be connected to the channel extension portion CHE of the channel structures CHS.

Thereafter, after the insulating capping lines BLCP, the first interlayer insulating layer (OBL of FIG. 4), the cell interconnection structure 170, and the inter-cell interconnection insulating layer 180 are formed to form the cell array structure CS as shown in FIG. 16, the upper metal pads 195 and the first bonding insulating layer 190 are formed on the cell array structure CS, the lower metal pads 295 and the second bonding insulating layer 290 are formed on the peripheral circuit structure PS and as shown in FIG. 17, the first bonding insulating layer 190 and the second bonding insulating layer 290 are brought into contact with each other, the upper metal pads 195 and the lower metal pads 295 corresponding to each other are brought into contact with each other to form the bonding pads MP, and then the carrier substrate 12, the lower adhesive layer 14, and the upper adhesive layer 16 are removed, thereby forming the semiconductor memory device 2.

Each of the lowermost ends of the word lines WL may be located at a vertical level that is lower than the lowermost ends of the mold structures MOL (i.e., lower surfaces of the mold layers MOLI) and higher than the lowermost ends of the gate dielectric films Gox and may be located at a vertical level that is lower than the upper surfaces of the contacts DCc.

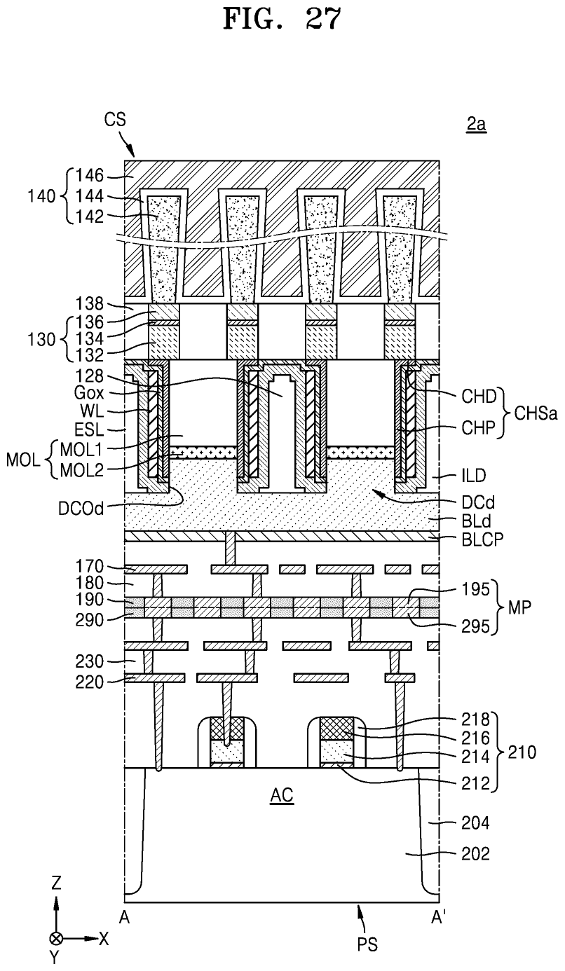

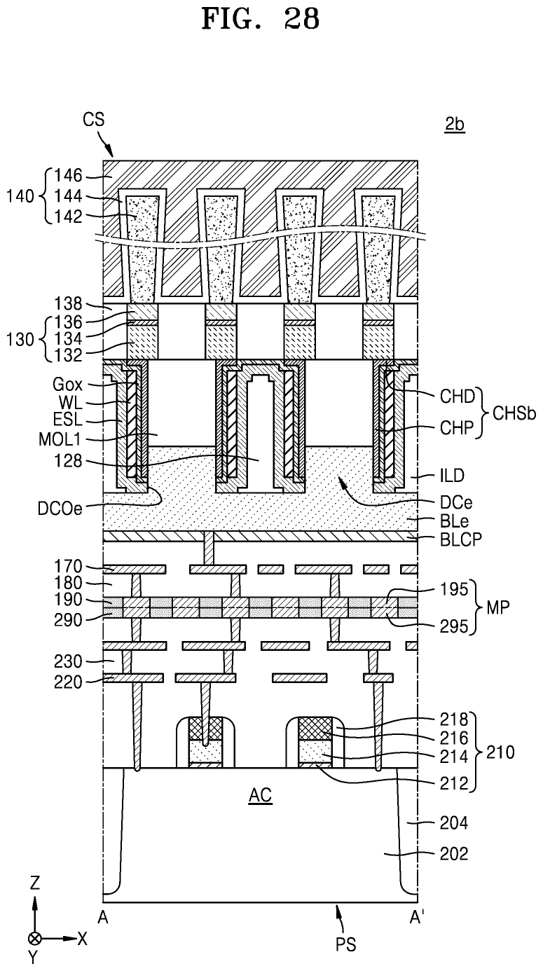

FIGS. 27 and 28 are cross-sectional views of semiconductor memory devices 2a and 2b according to embodiments, respectively. In detail, FIGS. 27 and 28 are each cross-sectional views taken along line A-A′ of FIG. 4.

Referring to FIG. 27, FIGS. 18A and 18B, FIGS. 19A and 19B, and FIG. 20, portions of the etch stop layer ESL, portions of the gate dielectric films Gox, the channel extension portion (CHE of FIG. 25) of the channel structures (CHS of FIG. 25), and portions of the mold structures MOL are removed to form a plurality of holes DCOd, and then, a plurality of bit lines BLd, which fill the holes DCOd, extend in the first horizontal direction (the X direction), and are repeatedly arranged to be apart from each other in the second horizontal direction (the Y direction), are formed on the etch stop layer ESL and the insulating patterns 128. The bit lines BLd may be formed to fill the holes DCOd and contact a channel pattern CHP and the channel extension portion (CHEa in FIG. 19A) of the channel structures CHSa. Portions of the bit lines BLd filling the holes DCOd may be the contacts DCd. The contacts DCd may be portions of the bit lines BLd that protrude toward the channel structures CHSa. The contacts DCd may pass through the etch stop layer ESL and the gate dielectric films Gox and be connected to the channel pattern CHP and the channel extension portion (CHEa in FIG. 19A) of the channel structures CHSa.

Thereafter, as shown in FIG. 26, after the insulating capping lines BLCP, the first interlayer insulating layer (OBL of FIG. 4), the cell interconnection structure 170, and the inter-cell interconnection insulating layer 180 are formed to form the cell array structure CS as shown in FIG. 16, the upper metal pads 195 and the first bonding insulating layer 190 are formed on the cell array structure CS, the lower metal pads 295 and the second bonding insulating layer 290 are formed on the peripheral circuit structure PS and as shown in FIG. 17, the first bonding insulating layer 190 and the second bonding insulating layer 290 are brought into contact with each other, the upper metal pads 195 and the lower metal pads 295 corresponding to each other are brought into contact with each other to form the bonding pads MP, and then the carrier substrate 12, the lower adhesive layer 14, and the upper adhesive layer 16 are removed, thereby forming the semiconductor memory device 2a.

Each of the lowermost ends of the word lines WL may be located at a vertical level that is lower than the lowermost ends of the mold structures MOL (i.e., lower surfaces of the mold structures MOL) and higher than the lowermost ends of the gate dielectric films Gox and may be located at a vertical level that is lower than the upper surfaces of the contacts DCd.

Referring to FIG. 28, after forming portions of the etch stop layer ESL, portions of the gate dielectric films Gox, the channel extension portions (CHE of FIG. 25) of the channel structures (CHS of FIG. 25), and portions of the mold structures MOL are removed to form a plurality of holes DCOe with reference to FIGS. 21A and 21B, 22A and 22B, and 23, and then, a plurality of bit lines Ble, which fill the holes DCOe, extend in the first horizontal direction (the X direction), and repeatedly arranged to be apart from each other in the second horizontal direction (the Y direction) on the etch stop layer ESL and the insulating patterns 128. The bit lines BLe may be formed to fill the holes DCOc and contact the channel pattern CHP and the channel extension portions (CHEb in FIG. 21A) of the channel structures CHSb. Portions of the bit lines BLe that fill the holes DCOc may be contacts DCe. The contacts DCe may be portions of the bit lines Ble that protrude toward the channel structures CHSb. The contacts DCe may pass through the etch stop layer ESL and the gate dielectric films Gox and be connected to the channel pattern CHP and the channel extension portions (CHEb in FIG. 21A) of the channel structures CHSb.

Thereafter, as shown in FIG. 26, after the insulating capping lines BLCP, the first interlayer insulating layer (OBL of FIG. 4), the cell interconnection structure 170, and the inter-cell interconnection insulating layer 180 are formed to form the cell array structure CS as shown in FIG. 16, the upper metal pads 195 and the first bonding insulating layer 190 are formed on the cell array structure CS, the lower metal pads 295 and the second bonding insulating layer 290 are formed on the peripheral circuit structure PS and as shown in FIG. 17, the first bonding insulating layer 190 and the second bonding insulating layer 290 are brought into contact with each other, the upper metal pads 195 and the lower metal pads 295 corresponding to each other are brought into contact with each other to form the bonding pads MP, and then the carrier substrate 12, the lower adhesive layer 14, and the upper adhesive layer 16 are removed, thereby forming the semiconductor memory device 2b.

Each of the lowermost ends of the word lines WL may be located at a vertical level that is lower than the lowermost ends of the mold structures MOL (i.e., lower surfaces of the first mold layers MOL1) and higher than the lowermost ends of the gate dielectric films Gox and may be located at a vertical level that is lower than the upper surfaces of the contacts DCe.

While the inventive concept has been particularly shown and described with reference to embodiments thereof, it will be understood that various changes in form and details may be made therein without departing from the spirit and scope of the inventive concept.

What is claimed is:

1. A semiconductor memory device comprising:
a bit line extending lengthwise in a first horizontal direction and including a contact;
a first channel structure and a second channel structure, each arranged in the first horizontal direction on the bit line and the first channel structure including a first channel pattern, a first channel pad portion, and a first channel extension portion, the second channel structure including a second channel pattern, a second channel pad portion, and a second channel extension portion, wherein the first channel pattern and the second channel pattern are spaced apart from one another in the first horizontal direction, the first channel pad portion extends horizontally from an upper end of the first channel pattern, the first channel extension portion extends horizontally from a lower end of the first channel pattern, the second channel pad portion extends horizontally from an upper end of the second channel pattern, and the second channel extension portion extends horizontally from a lower end of the second channel pattern; and
a first word line and a second word line each extending lengthwise in a second horizontal direction orthogonal to the first horizontal direction and arranged adjacent to a respective channel pattern of the first channel structure and the channel pattern of the second channel structure,
wherein the contact of the bit line is connected to the first channel extension portion and the second channel extension portion.

2. The semiconductor memory device of claim 1, wherein the channel pad portion of the first channel structure and the channel pad portion of the second channel structure extend away from each other in opposite directions in the first horizontal direction.

3. The semiconductor memory device of claim 1, wherein, an extension direction of the first channel pad portion in the first horizontal direction from the upper end of the first channel pattern is opposite to an extension direction of the first channel extension portion in the first horizontal direction from the lower end of the first channel pattern and an extension direction of the second channel pad portion in the first horizontal direction from the upper end of the second channel pattern is opposite to an extension direction of the second channel extension portion in the first horizontal direction from the lower end of the second channel pattern.

4. The semiconductor memory device of claim 1, further comprising:
a mold structure disposed between the first channel pattern and the second channel pattern on the bit line,
wherein the first channel extension portion and the second channel extension portion form a channel extension shared by the first channel structure and the second channel structure and that covers a lower surface of the mold structure, and
a lowermost end of each of the first word line and the second word line is at a vertical level lower than a lower surface of the mold structure.

5. The semiconductor memory device of claim 4, further comprising:
a gate dielectric film provided between the first channel structure and the first word line and between the second channel structure and the second word line,
wherein the lowermost end of each of the first word line and the second word line is at a vertical level higher than a lowermost end of the gate dielectric film.

6. The semiconductor memory device of claim 5, wherein the contact of the bit line fills a hole penetrating through the gate dielectric film.

7. The semiconductor memory device of claim 5, further comprising:
an etch stop layer covering lower portions of the gate dielectric film, the first word line, and the second word line, the etch stop layer disposed on the bit line,
wherein the contact of the bit line passes through the etch stop layer and the gate dielectric film and is connected to the first channel extension portion and the second channel extension portion.

8. The semiconductor memory device of claim 1, wherein the contact of the bit line passes through the first channel extension portion and the second channel extension portion and is connected to a first sidewall the first channel pattern and a second sidewall of the second channel pattern, wherein the first sidewall opposes the second sidewall.

9. The semiconductor memory device of claim 1, wherein each of the first channel structure and the second channel structure includes an oxide semiconductor material.

10. The semiconductor memory device of claim 1, further comprising:
a first contact plug connected to the first channel pad portion and a second contact plug connected to the second channel pad portion; and
a first capacitor structure disposed on the first contact plug and a second capacitor structure formed on the second contact plug.

11. A semiconductor memory device comprising:
a bit line extending lengthwise in a first horizontal direction and including a contact that protrudes upwards from a surface of the bit line;
a plurality of mold structures arranged on the bit line, the plurality of mold structures extending in a second horizontal direction orthogonal to the first horizontal direction, and arranged spaced apart from each other in the first horizontal direction;
first channel structures and a second channel structures, arranged to alternate between a first channel structure and a second channel structure in the first horizontal direction on the bit line;
a first word line extending lengthwise in the second horizontal direction and arranged adjacent to the first channel structure and a second word line extending lengthwise in the second horizontal direction and arranged adjacent to the second channel structure;
a gate dielectric film provided between the first channel structure and the first word line and between the second channel structure and the second word line;
a first contact plug disposed on the first channel structure and a second contact plug disposed on the second channel structure, the first contact plug connected to the first channel structure and the second contact plug connected to the second channel structure; and
a capacitor including a lower electrode disposed on the first contact plug and connected to the first contact plug, a capacitor dielectric film covering the lower electrode, and an upper electrode disposed on the capacitor dielectric film,
wherein each of the first channel structures include a first channel pattern extending in a vertical direction along a first sidewall of a corresponding mold structure of the plurality of mold structures, a first channel pad portion extending away from the corresponding mold structure in the first horizontal direction from an upper end of the first channel pattern, and a first channel extension portion extending along a lower surface of the corresponding mold structure from a lower end of the first channel pattern, and each of the second channel structures includes a second channel pattern extending in a vertical direction along a second sidewall of the corresponding mold structure opposite the first sidewall, a second channel pad portion extending away from the corresponding mold structure in a direction opposite to the extension direction of the first channel pad portion from an upper end of the second channel pattern, and a second channel extension portion extending along a lower surface of the corresponding mold structure from a lower end of the second channel pattern opposite the upper end and, the first contact plug is connected to the first channel pad portion, the second contact plug is connected to the second channel pad portion, and the contact of the bit line is connected to the first channel extension portion and the second channel extension portion.

12. The semiconductor memory device of claim 11, further comprising:
an insulating pattern covering the first word line and the second word line and filling a space between a pair of mold structures that are adjacent in the first horizontal direction among the plurality of mold structures,
wherein the insulating pattern covers a lowermost end of each of the first word line and the second word line facing the bit line in the vertical direction.

13. The semiconductor memory device of claim 12, wherein a lower surface of the insulating pattern is located at the same vertical level as a lowermost end of the gate dielectric film.

14. The semiconductor memory device of claim 11, wherein a lowermost end of each of the first word line and the second word line is at a vertical level lower than the lower surface of the mold structure and higher than a lowermost end of the gate dielectric film.

15. The semiconductor memory device of claim 11, wherein
the gate dielectric film has a hole penetrating through the gate dielectric film, and
the contact of the bit line fills the hole.

16. The semiconductor memory device of claim 15, wherein the hole penetrates through the gate dielectric film, the first channel extension portion, and the second channel extension portion, and the contact of the bit line extends upwards through the first channel extension portion and the second channel extension portion so as to be connected to portions of opposing sidewalls of each of the first channel pattern and the second channel pattern.

17. The semiconductor memory device of claim 11, wherein a sidewall of the first word line faces a sidewall of the first channel pattern with a first portion of the gate dielectric film disposed therebetween and a sidewall of the second word line faces a sidewall of the second channel pattern with a second portion of the gate dielectric film disposed there between, wherein the sidewall of the first word line opposes the sidewall of the second word line and the sidewall of the first channel pattern opposes the sidewall of the second channel pattern.

18. A semiconductor memory device comprising:
a peripheral circuit structure including a peripheral circuit substrate and circuit gate structures, wherein the peripheral circuit substrate has a plurality of active regions defined by a circuit device separator, and each of the circuit gate structures is disposed in a corresponding active region of the plurality of active regions of the peripheral circuit substrate and forms a peripheral circuit transistor; and
a cell array structure overlapping the peripheral circuit structure in a vertical direction,
wherein the cell array structure includes:
a bit line extending lengthwise in a first horizontal direction and including a contact that protrudes upwards from the bit line;
a plurality of mold structures arranged on the bit line, the plurality of mold structures extending in a second horizontal direction orthogonal to the first horizontal direction, and arranged to be spaced apart from each other in the first horizontal direction;
a first channel structure and a second channel structure, arranged in the first horizontal direction on the bit line;
a first word line and a second word line each extending lengthwise in the second horizontal direction and arranged with the first word line adjacent to the first channel structure and the second word line adjacent to the second channel structure;
a gate dielectric film provided between the first channel structure and the first word line and between the second channel structure and the second word line and having a hole filled with the contact of the bit line;
an insulating pattern covering the first word line and the second word line and filling spaces between pairs of mold structures that are adjacent in the first horizontal direction among the plurality of mold structures;
a first contact plug disposed on the first channel structure and connected to the first channel structure and a second contact plug disposed on the second channel structure and connected to the second channel structure; and
a capacitor disposed on the first contact plug and including a lower electrode connected to the first contact plug, an upper electrode, and a capacitor dielectric film provided between the lower electrode and the upper electrode,
wherein the first channel structure includes a first channel pattern extending in the vertical direction along a first sidewall a mold structure of the plurality of mold structures in the first horizontal direction, a first channel pad portion extending away from the mold structure in the first horizontal direction from an upper end of the first channel pattern and connected to the first contact plug, and a first channel extension portion extending along a lower surface of the mold structure from the lower end of the first channel pattern, and the second channel structure includes a second channel pattern extending in the vertical direction along a second sidewall of the mold structure opposite the first sidewall, a second channel pad portion extending away from the mold structure in the first horizontal direction from an upper end of the second channel pattern in an extension direction opposite that of the first channel pad portion and connected to the second contact plug, and a second channel extension portion extending along a lower surface of the mold structure from the lower end of the second channel pattern, the first channel extension portion and the second channel extension portion connected to the contact of the bit line.

19. The semiconductor memory device of claim 18, wherein
a lower surface of the insulating pattern is at the same vertical level as a lowermost end of the gate dielectric film, and
the insulating pattern covers a lowermost end of each of the first word line and the second word line facing the bit line in the vertical direction.

20. The semiconductor memory device of claim 18, wherein
a lowermost end of each of the first word line and the second word line is at a vertical level lower than a lower surface of the mold structure and higher than a lowermost end of the gate dielectric film, and
each of the first channel structure and the second channel structure includes IGZO.
